(19) United States
(12) Patent Application Publication
(10) Pub. No.: US 2026/0190786 A1
(43) Pub. Date: Jul. 2, 2026

(54) DISPLAY DEVICE

(71) Applicant: LG Display Co., Ltd., Seoul (KR)

(72) Inventors: Soobin BAE, Paju-si (KR); JungWoo HAN, Paju-si (KR); ChangDuk HA, Paju-si (KR); JaeHyun RYU, Paju-si (KR)

(73) Assignee: LG Display Co., Ltd., Seoul (KR)

(21) Appl. No.: 19/426,785

(22) Filed: Dec. 19, 2025

(30) Foreign Application Priority Data
Dec. 30, 2024 (KR) 10-2024-0199954

(51) Int. Cl. H10K 59/80; H10K 59/122; H10K 59/123; H10K 59/124; H10K 59/131; H10K 102/00

(52) U.S. Cl. CPC H10K 59/873; H10K 59/122; H10K 59/123; H10K 59/124; H10K 59/131; H10K 59/8723; H10K 2102/351

(57) ABSTRACT

A display device may include a planarization layer disposed over a substrate, located in a display area, and extending to a portion of a non-display area, a first mid-stopper located in the non-display area and disposed outside the planarization layer, a second mid-stopper disposed outside the first mid-stopper, a first metal pattern located in the non-display area and disposed on the first mid-stopper and the second mid-stopper, a second metal pattern located in the non-display area and disposed on the first metal pattern, and a first trench located between the first mid-stopper and the second mid-stopper. In one or more aspects, the first and second metal patterns may be disconnected at the first trench. The display device can prevent overflow of an organic encapsulation layer and damage to a stackup structure during the manufacturing process, and block a moisture penetration path from the non-display area to the display area.

### CROSS-REFERENCE TO RELATED APPLICATION

This application claims the benefit of and priority to Korean Patent Application No. 10-2024-0199954, filed on Dec. 30, 2024 in the Korean Intellectual Property Office, the entire contents of which are incorporated herein by reference for all purposes as if fully set forth herein.

### TECHNICAL FIELD

The present disclosure relates to electronic devices, and more specifically, for example, without limitation, to display devices.

### BACKGROUND

In today's information society, display devices for presenting images or visual information to users are increasingly important. The need for such display devices has caused display technology to be rapidly developed, and various types of display devices, such as a liquid crystal display (LCD) device, an organic light emitting display (OLED) device, an inorganic light emitting display (iLED) device, a micro light emitting display (micro LED) device, a mini light emitting displays (mini LED) device, a quantum dot light emitting display (QLED) device, and the like, have been developed and widely used.

In particular, an organic light emitting display device employing a self-emissive light emitting element can be manufactured in a thinner and lighter package because a separate back-light unit is not needed, compared with other types of display devices, such as a liquid crystal display (LCD) device. Further, the organic light emitting display device consumes much less power based on a low voltage operating, and has excellent color reproduction, a faster response speed, a wider viewing angle, and a higher contrast ratio. As the organic light emitting display device has such excellent performance, work has been progressing on applying in various field of devices, apparatuses, systems, and the like.

An organic light emitting element such as an organic light emitting diode included in an organic light emitting display device may be damaged, for example, reduction in light emitting efficiency or performance, by undesired substances such as moisture and oxygen. To prevent the penetration of such undesired substances, an encapsulation layer may be disposed on the organic light emitting element during the process of manufacturing the organic light emitting display device. For example, an encapsulation layer may be formed by alternately stacking at least one organic encapsulation layer and at least one inorganic encapsulation layer to prevent oxygen, moisture, and the like from penetrating an organic emission layer and electrodes.

The description in the background section should not be considered prior art merely because it is mentioned in or associated with this section. The description in the background section includes information that describes one or more aspects of the subject technology, and the description in this section does not limit the scope of the invention.

### SUMMARY

One or more aspects of the present disclosure may provide a display device having a structure capable of preventing a portion of an encapsulation layer from overflowing during the process of manufacturing the display device.

One or more aspects of the present disclosure may provide a display device having a structure capable of preventing undesired substances such as moisture, oxygen, and the like from penetrating into a display area due to damage to a stackup structure of a display panel.

One or more aspects of the present disclosure may provide a display device capable of blocking a penetration path of undesired substances such as moisture, oxygen, and the like through metal from a non-display area to a display area.

One or more aspects of the present disclosure may provide a display device capable of minimizing damage to a stackup structure (hereinafter, which may represent, for example, a stack of metal layers or elements used as a signal line, a connection electrode, and/or the like) due to gas generated or emitted from various structures or configurations including organic materials during the process of manufacturing the display device.

One or more aspects of the present disclosure may provide a display device having a structure capable of preventing damage to a light emitting element that may occur by the process of manufacturing the display device.

One or more aspects of the present disclosure may provide a display device having a structure capable of preventing damage to a light emitting element in a display area and resulting display artifacts such as dark spots due to the penetration of undesired substances such as moisture, oxygen, and the like in a non-display area.

Aspects, examples, and embodiments for solving issues or problems in the present disclosure are not limited to the foregoing description, and aspects, examples, and embodiments for solving other issues or problems will become apparent to those skilled in the art from the following description.

According to one or more example embodiments of the present disclosure, a display device can be provided that includes a substrate, a display area for displaying an image and a non-display area outside of the display area, a planarization layer disposed over the substrate, located in the display area, and extending to a portion of the non-display area, a first mid-stopper located in the non-display area and disposed outside of the planarization layer, a second mid-stopper disposed outside of the first mid-stopper, a first metal pattern located in the non-display area and disposed on the first mid-stopper and the second mid-stopper, a second metal pattern located in the non-display area and disposed on the first metal pattern, and a first trench located between the first mid-stopper and the second mid-stopper. In one or more aspects, the first metal pattern and the second metal pattern may be disconnected at the first trench.

According to one or more example embodiments of the present disclosure, a display device can be provided that includes a substrate, a display area for displaying an image and a non-display area outside of the display area, a planarization layer disposed over the substrate and extending from the display area to a portion of the non-display area, a common electrode disposed on the planarization layer and extending from the display area to a portion of the non-display area, a first mid-stopper disposed outside of the planarization layer and surrounding the display area, a second mid-stopper surrounding the first mid-stopper and spaced apart from the first mid-stopper, a trench located between the first mid-stopper and the second mid-stopper, and a metal pattern located in the non-display area, disposed on the first mid-stopper and the second mid-stopper, and disconnected at the trench. In one or more aspects, a portion of the metal pattern disposed on the first mid-stopper may be electrically connected to the common electrode.

According to one or more aspects of the present disclosure, a display device may be provided that has a structure capable of preventing a portion of an encapsulation layer from overflowing during the process of manufacturing the display device.

According to one or more aspects of the present disclosure, a display device may be provided that has a structure capable of preventing undesired substances such as moisture, oxygen, and the like from penetrating into a display area due to damage to a stackup structure of a display panel.

According to one or more aspects of the present disclosure, a display device may be provided that is capable of blocking a penetration path of undesired substances such as moisture, oxygen, and the like through metal from a non-display area to a display area.

According to one or more aspects of the present disclosure, a display device may be provided that is capable of minimizing damage to a stackup structure due to gas generated or emitted from various structures or configurations including organic materials during the process of manufacturing the display device.

According to one or more aspects of the present disclosure, a display device may be provided that has a structure capable of preventing damage to a light emitting element that may occur by the process of manufacturing the display device.

According to one or more aspects of the present disclosure, a display device may be provided that has a structure capable of preventing damage to a light emitting element in a display area and resulting display artifacts such as dark spots due to the penetration of undesired substances such as moisture, oxygen, and the like in a non-display area.

According to one or more aspects of the present disclosure, a display device may be provided that is capable of preventing the penetration of undesired substances such as moisture, oxygen, and the like from the outside, to the inside, of a display panel during the process of manufacturing the display device, and thereby, preventing elements (e.g., light emitting elements, signal lines, electrodes, and the like) disposed inside of the display panel from being damaged or an electrical short circuit from occurring by the undesired substances.

According to one or more aspects of the present disclosure, a display device may be provided that has a structure capable of preventing the penetration of undesired substances such as moisture, oxygen, and the like by utilizing one or more structures or configurations used in a display panel without adding a separate layer or pattern.

Effects or advantages according to aspects, examples, and embodiments of the present disclosure are not limited to the foregoing description, and other effects or advantages will become apparent to those skilled in the art from the following description.

Aspects, examples, and embodiments discussed herein will be more fully understood from the detailed description and accompanying drawings provided below. It should be understood here that since alternative aspects, examples, and embodiments may add, omit, or change elements, structures, configurations, and the like, therefore, aspects, examples, and embodiments described herein are not meant to be limitations.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a plan view of an example display panel according to aspects of the present disclosure;

FIG. 2 illustrates a system configuration of an example display device according to aspects of the present disclosure;

FIG. 3 illustrates an example configuration of the display panel according to aspects of the present disclosure;

FIG. 4 illustrates an example equivalent circuit of at least one subpixel included in the display device according to aspects of the present disclosure;

FIG. 5 is an example cross-sectional view of the display panel according to aspects of the present disclosure;

FIG. 6 is an example simplified cross-sectional view of the display device according to aspects of the present disclosure;

FIG. 7 illustrates example moisture penetration that may occur due to damage to a stackup structure of the display panel;

FIGS. 8 and 9 are example simplified cross-sectional views of the display panel according to aspects of the present disclosure;

FIG. 10 illustrates an example where a trench serves to prevent an organic encapsulation layer from overflowing in the display device according to aspects of the present disclosure; and

FIG. 11 illustrates an example where moisture penetration is blocked in the display device according to aspects of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to,” “contact,” “overlap with,” or the like each other via a fourth element. Here, the second element may be included in at least one of two or more elements that “are connected or coupled to,” “contact,” “overlap with,” or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom,” “downward,” “upward,” “upper,” “lower,” and the like refer to an arbitrary frame of reference.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom,” “downward,” “upward,” “upper,” “lower,” and the like refer to an arbitrary frame of reference.

In addition, when any dimensions, relative sizes, and the like are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can.”

Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

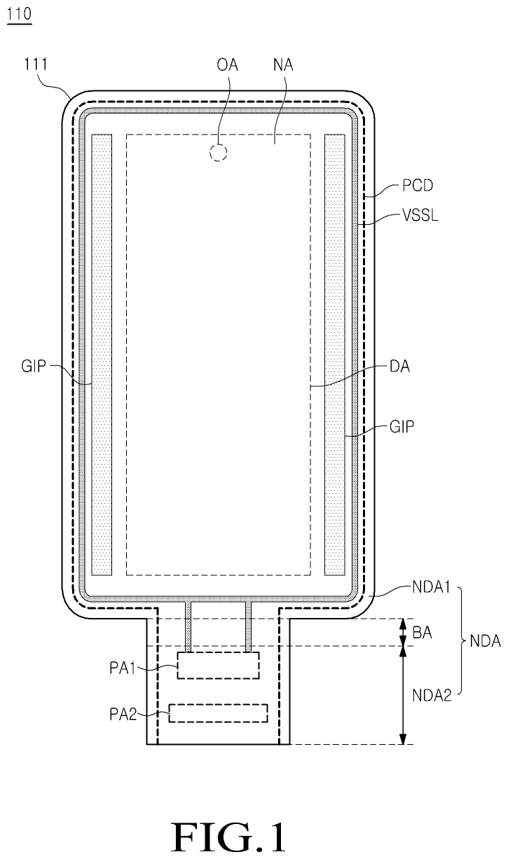

FIG. 1 is a plan view of an example display panel 110 according to aspects of the present disclosure.

Referring to FIG. 1, in one or more example embodiments, a bending structure and a wiring structure may be formed in the display panel 110.

Referring to FIG. 1, in one or more aspects, a substrate 111 of the display panel 110 may include a display area DA and a non-display area NDA. The display area DA and the non-display area NDA may be areas defined in the display panel 110.

For example, one or more lines, one or more electrodes, and the like may be disposed on the substrate 111. In a display device according to one or more aspects, the substrate 111 included in the display panel 110 may be a flexible substrate that can be bent in a certain range of angles. In this specification, “bending or bent” may have the same meaning as “folding or folded” or “flexible.”

The non-display area NDA may be an area where an image is not displayed and may be an area except for the display area DA. Subpixels SP may not be disposed in the non-display area NDA. In one or more aspects, at least one dummy subpixel, which is not directly involved in image displaying, may be disposed in the non-display area NDA.

In one or more aspects, the non-display area NDA may include a first non-display area NDA), a bending area BA, and a second non-display area NDA2.

The first non-display area NDA1 may be located outside of the display area DA, and may be an area that is closest to the display area DA among the first non-display area NDA1, the bending area BA, and the second non-display area NDA2.

The second non-display area NDA2 may include a pad area allowing several pads to be disposed and including, for example, a first pad area PA1 and a second pad area PA2. For example, the pad area may be located farthest away from the display area DA among the first non-display area NDA1, the bending area BA, and the second non-display area NDA2. The first pad area PA1 may be an area to which a driving circuit (e.g., a driving integrated circuit including a data driving circuit and a touch driving circuit) is bonded or connected. The second pad area PA2 may be an area to which a printed circuit board is connected. Several types of electronic components such as a display controller, a touch controller, and the like may be mounted on the printed circuit board.

The bending area BA may be an area allowing the substrate 111 to be bent, and be located between the first non-display area NDA1 and the second non-display area NDA2.

The substrate 111 may include the display area DA where an image is displayed and the non-display area NDA located outside of the display area DA.

A plurality of subpixels SP may be disposed in the display area DA.

In one or more aspects, the non-display area NDA may include a gate-in-panel (GIP) area where a gate driving circuit implemented by a gate-in-panel (GIP) technique is disposed, the bending area BA where a plurality of lines run and a data driving circuit is electrically connected, and the second non-display area NDA2, and the like.

For example, the gate-in-panel (GIP) area may be located in an area adjacent to, or contacting, a left outer edge of the display area DA and/or an area adjacent to, or contacting, a right outer area thereof.

In one or more aspects, the non-display area NDA may include an upper non-display area adjacent to, or contacting, an upper outer edge of the display area DA and a lower non-display area adjacent to, or contacting, a lower outer edge thereof.

The second non-display area NDA2 may be an area further outwardly located from the display area DA than the bending area BA, and may include the pad area (e.g., including the first pad area PA1 and the second pad area PA2) to which at least one circuit component such as a printed circuit board is electrically connected.

As described above, the substrate 111 may include the bending area BA, which can be bent or folded, and when being bent or folded, the bending area BA may be located on the lower surface of a portion of the substrate 111 that is not bent or folded.

The bending area BA may be a portion of the non-display area NDA, and may be located between a driving circuit area to which a data driving circuit is electrically connected, and the display area DA.

The display panel 110 may include the substrate 111 and a plurality of subpixels SP disposed on the substrate 111. In one or more aspects, the display panel 110 may further include several types of signal lines to drive the plurality of subpixels SP.

For example, to drive at least one subpixel SP, at least one driving voltage line VDDL for delivering a driving voltage VDD, which is a type of common voltage, to the at least one subpixel SP, and at least one base voltage line VSSL for delivering a base voltage VSS, which is a type of common voltage, to a common electrode CE of a corresponding light emitting element ED of the at least one subpixel SP, and the like may be further disposed on the substrate 111.

The base voltage VSS may be referred to as a first common voltage, a low common voltage, a low driving voltage, or the like, and the base voltage line VSSL may also be referred to as a first common voltage line, a low common voltage line, a low driving voltage line, or the like. The driving voltage VDD may be referred to as a second common voltage, a high common voltage, a high driving voltage, or the like, and the driving voltage line VDDL may also be referred to as a second common voltage line, a high common voltage line, a high driving voltage line, or the like.

For example, a plurality of driving voltage lines VDDL may be disposed in a column direction, but aspects of the present disclosure are not limited thereto. To efficiently delivering the driving voltage VDD to the plurality of driving voltage lines VDDL, driving voltage patterns, which are integrally formed as a single unit with, or electrically connected to the plurality of driving voltage lines VDDL, respectively, may be disposed in the non-display area NDA.

The plurality of driving voltage lines VDDL may electrically interconnect, through the driving voltage patterns, the bending area BA and a data driving circuit or a printed circuit board connected to the pad area (e.g., the first pad area PA1 and/or the second pad area PA2).

To efficiently deliver the base voltage VSS, for example, one or more base voltage lines VSSL may be disposed in the non-display area NDA such that the one or more base voltage lines VSSL surround an outer edge of the display area DA. In one or more aspects, the one or more base voltage lines VSSL may pass through the bending area BA and be electrically connected to a data driving circuit or a printed circuit board connected to a driving circuit area.

A crack prevention pattern PCD may be disposed on the substrate 111. The crack prevention pattern PCD may be disposed in a portion of the non-display area NDA located further outwardly from the display area DA than the one or more base voltage lines VSSL, but aspects of the present disclosure are not limited thereto.

For example, the crack prevention pattern PCD may be a pattern for preventing lines running on the substrate 111 from being cracked. In one or more aspects, the crack prevention pattern PCD may be disposed in a zigzag pattern, but aspects of the present disclosure are not limited thereto.

For example, one or more signal lines among signal lines passing through the bend area BA may be cracked (e.g., electrically disconnected) or form a short circuit with adjacent one or more signal lines when the bending area BA is bent. In this case, since signals cannot be delivered accurately through the cracked (e.g., electrically disconnected) lines or the short-circuited signal lines, display driving may not be normally performed, which may prevent proper image display and significantly deteriorate image quality. To address these issues, one or more crack prevention patterns PCD may be disposed in the display panel 110. It should be noted that configurations of crack prevention patterns PCD according to aspects of the present disclosure are not limited thereto.

As described above, the display panel 110 may use a flexible substrate 111 and allow the bending area BA to which a data drive circuit is connected to be bent. In this configuration, when the bending area BA is bent, a portion of the substrate 111 can be folded backwardly or forwardly in a certain range of angles. The folded portion of the bending area BA may be a portion in which an image is not displayed and be invisible in front of the display panel 110.

Therefore, as the display panel 110 employs the bending structure and line arrangement structure as in FIG. 1, the display panel 110 can provide an advantage of significantly reducing a bezel size of a display device.

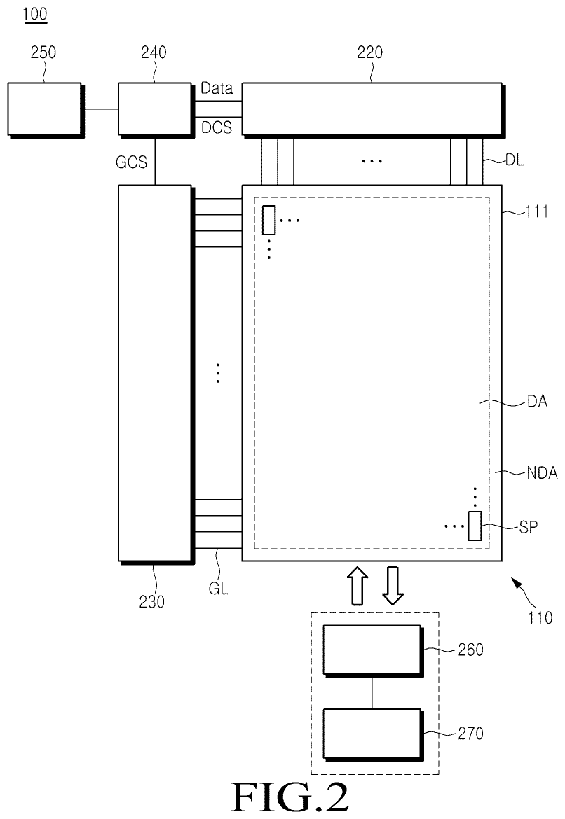

FIG. 2 illustrates an example system configuration of a display device 100 according to aspects of the present disclosure.

Referring to FIG. 2, in one or more example embodiments, the display device 100 may include the display panel 110 and a display driving circuit as components for displaying images.

The display driving circuit may be a circuit for driving the display panel 110, and include a data driving circuit 220, a gate driving circuit 230, a display controller 240, and other circuit components.

The display panel 110 may include a display area DA in which images can be displayed and a non-display area NDA in which an image is not displayed. The non-display area NDA may be an area outside of the display area DA, and may also be referred to as a non-active area, an edge area, or a bezel area.

The display panel 110 may include a substrate 111 and a plurality of subpixels SP disposed on the substrate 111. In one or more aspects, the display panel 110 may further include several types of signal lines to drive the plurality of subpixels SP.

In one or more aspects, the display device 100 herein may be a liquid crystal display device, or the like, or a self-emission display device in which light is emitted from the display panel PNL itself. In an example where the display device 100 is a self-emission display device, each of the plurality of subpixels SP may include a light emitting element. For example, the display device 100 may be an organic light emitting display device in which the light emitting element is implemented using an organic light emitting diode (OLED).

The structure of each of the plurality of subpixels SP may vary according to types of display devices. In an example where the display device 100 is a self-emission display device including self-emission subpixels SP, each subpixel SP may include a self-emission light emitting element, one or more transistors, and one or more capacitors.

In one or more aspects, several types of signal lines disposed in the display device 100 may include, for example, a plurality of data lines DL for carrying data signals (which may be referred to as data voltages or image signals), a plurality of gate lines GL for carrying gate signals (which may be referred to as scan signals), and the like.

The plurality of data lines DL and the plurality of gate lines GL may intersect one another. Each of the plurality of data lines DL may extend in a first direction. Each of the plurality of gate lines GL may extend in a second direction different from the first direction. For example, the first direction may be the column or vertical direction, and the second direction may be the row or horizontal direction. In another example, the first direction may be the row or horizontal direction, and the second direction may be the column or vertical direction.

The data driving circuit 220 may be a circuit for driving the plurality of data lines DL, and can supply data signals to the plurality of data lines DL. The gate driving circuit 230 may be a circuit for driving the plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data Data based on the input image data to the data driving circuit 220.

The data driving circuit 220 can receive digital image data Data from the display controller 240, convert the received image data Data into analog data signals, and output the resulting analog data signals to the plurality of data lines DL.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more embodiments, the gate driving circuit 230 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In one or more embodiments, the gate driving circuit 230 may be disposed in the non-display area NDA of the display panel 110 by a gate-in-panel (GIP) technique. The gate driving circuit 230 may be disposed on the substrate, or connected to the substrate. In an example where the gate driving circuit 230 is implemented by the GIP technique, the gate driving circuit 230 may be disposed in the non-display area NDA of the substrate. The gate driving circuit 230 may be connected to the substrate in the case of the chip-on-glass (COG) type, the chip-on-film (COF) type, or the like.

In one or more embodiments, at least one of the data driving circuit 220 and the gate driving circuit 230 may be disposed in the display area DA of the display panel 110. For example, at least one of the data driving circuit 220 and the gate driving circuit 230 may be disposed not to overlap with subpixels SP, or disposed to be overlapped with one or more, or all, of the subpixels SP.

The data driving circuit 220 may be located in, and/or electrically connected to, but not limited to, only one side or edge (e.g., an upper portion or a lower portion) of the display panel 110. In one or more aspects, the data driving circuit 220 may be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 230 may be located in, and/or electrically connected to, but not limited to, only one side or edge (e.g., a left portion or a right portion) of the display panel 110. In one or more aspects, the gate driving circuit 230 may be located in, and/or electrically connected to, but not limited to, two sides or edges (e.g., a left portion and a right portion) of the panel 110 or at least two of four sides or edges (e.g., an upper portion, a lower portion, the left portion, and the right portion) of the panel 110 according to driving schemes, panel design schemes, or the like.

The display controller 240 may be implemented in a separate component from the data driving circuit 220, or incorporated in the data driving circuit 220 and thus implemented in an integrated circuit.

In one or more example embodiments, to further provide a touch sensing function, as well as an image display function, the display device 100 may include at least one touch sensor, and a touch sensing circuit configured to detect whether a touch event occurs, which is caused by a touch object such as a finger, a pen, or the like, or to detect a corresponding touch position, by sensing the touch sensor. It should be noted herein that a touch sensor may be referred to as all, or one or more, of a plurality of touch electrodes included in the display panel 110 according to design requirements.

The touch sensing circuit may include a touch driving circuit 260 capable of generating and providing touch sensing data by driving and sensing the touch sensor, a touch controller 270 capable of detecting the occurrence of a touch event or detecting a touch location (or touch coordinates) using the touch sensing data, and the like.

The touch sensor may include a plurality of touch electrodes. The touch sensor may further include a plurality of touch lines for electrically connecting the plurality of touch electrodes to the touch driving circuit 260.

The touch sensor may be implemented in the form of a touch panel outside of the display panel 110 or be integrated inside of the display panel 110.

In the example where the touch sensor is integrated to the inside of the display panel 110, the touch sensor may be formed over the substrate 111 together with signal lines and electrodes related to display driving during the process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In one or more aspects, the touch driving circuit 260 and the touch controller 270 included in the touch sensing circuit may be implemented in separate devices or be integrated into a single device. In one or more aspects, the touch driving circuit 260 and the data driving circuit 220 may be implemented in separate devices, or be integrated into a single device.

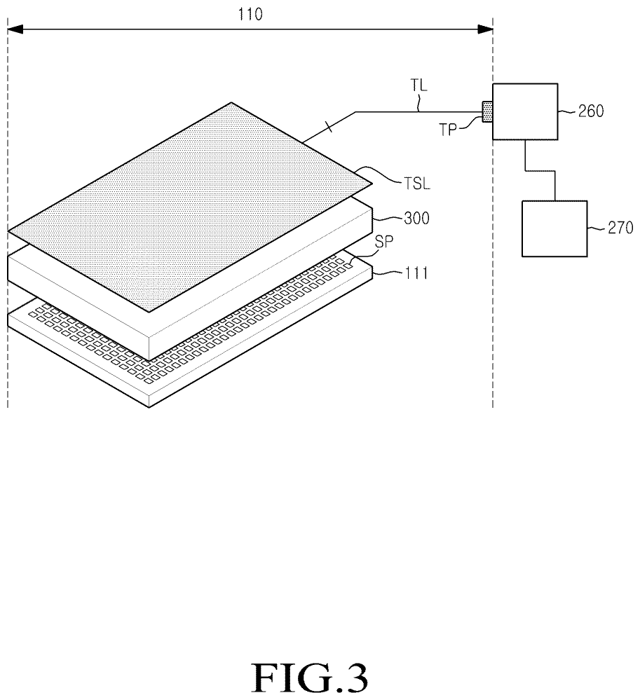

FIG. 3 illustrates an example configuration of the display panel 110 according to aspects of the present disclosure.

Referring to FIG. 3, in one or more example embodiments, a plurality of subpixels SP may be disposed in the display area DA of the display panel 110. The plurality of subpixels SP may be disposed in a normal area and at least one optical area included in the display area DA of the display panel 110. The at least one first optical area OA may be an area having a transmittance greater than the normal area NA.

Referring to FIG. 3, in one or more example embodiments, to detect a touch application by a user, the display device 100 may include a touch sensor layer TSL including a plurality of sensor electrodes, the touch driving circuit 260 configured to sense the plurality of sensor electrodes, and the touch controller 270 configured to determine whether a touch is applied or a location of the touch (e.g., touch coordinates) based on the sensing result (e.g., touch sensing data) of the touch driving circuit 260.

Since circuit elements (e.g., a light emitting element ED such as an organic light emitting diode (OLED) including an organic material in each subpixel SP may be easily damaged by external moisture or oxygen, an encapsulation layer 300 may be disposed in the display panel 110 to prevent the external moisture or oxygen from penetrating the circuit elements (e.g., the light emitting element ED). The encapsulation layer 300 may be disposed such that it covers one or more light emitting elements ED.

The touch sensor layer TSL may be integrated into the display panel 110. For example, the touch sensor layer TSL may be disposed on the encapsulation layer 300 in the display panel 110.

The display panel 110 may further include a plurality of touch pads TP to which the touch driving circuit 260 is electrically connected, and a plurality of touch routing lines TL for electrically connecting the plurality of sensor electrodes included in the touch sensor layer TSL to the plurality of touch pads TP to which the touch driving circuit 260 is electrically connected.

The touch routing lines TL and the touch pads TP may be disposed in the display panel 110.

For example, the touch pads TP may be disposed in a first pad area PA1 (e.g., the first pad area PA1 of FIG. 1) in the non-display area NDA. The touch routing lines TL may be disposed in the non-display area NDA and be electrically connected to touch pads TP disposed in the first pad area PA1.

The touch driving circuit 260 may be bonded to the first pad area PA1 in the non-display area NDA and be electrically connected to touch pads TP disposed in the first pad area PA1.

The touch controller 270 may be mounted on a printed circuit board connected to a second pad area PA2 (e.g., the second pad area PA2 of FIG. 1) in the non-display area NDA.

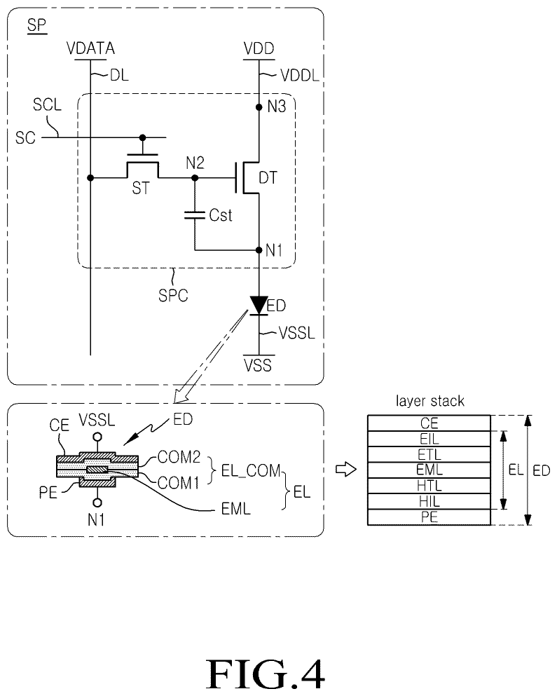

FIG. 4 illustrates an example equivalent circuit of at least one subpixel included in the display device 100 according to aspects of the present disclosure.

Referring to FIG. 4, in one or more example embodiments, a subpixel circuit SPC included in each subpixel SP may include a driving transistor DT for driving a light emitting element ED, a scan transistor ST for transferring a data voltage Vdata to the driving transistor DT, a storage capacitor Cst for maintaining a voltage at a certain level during one frame or one or more periods of periods of one frame, and the like.

The driving transistor DT may include a first node N1, a second node N2, and a third node N3.

The first node N1 may be a node electrically connected to the light emitting element ED. The second node N2 may be a node electrically connected to a scan transistor ST. The third node N3 may be a node electrically connected to a driving voltage line VDDL.

The first node N1 may be electrically connected to a pixel electrode PE of the light emitting element ED. A data voltage VDATA may be applied to the second node N2. A driving voltage VDD may be applied to the third node N3. The driving voltage VDD may be referred to as a second common voltage, a high common voltage, a high driving voltage, or the like, and the driving voltage line VDDL may also be referred to as a second common voltage line, a high common voltage line, a high driving voltage line, or the like.

For example, the second node N2 may be a gate node of the driving transistor DT, the first node N1 may be a source node or a drain node of the driving transistor DT, and the third node N3 may be the drain node or the source node of the driving transistor DT. Hereinafter, for merely convenience of explanation, discussions may be provided based on examples where the first, second, and third nodes (N1, N2, and N3) are source, gate, and drain nodes of the driving transistor DT, respectively. However, aspects of the present disclosure are not limited thereto.

The light emitting element ED may include a pixel electrode PE, an intermediate layer EL, and a common electrode CE.

The pixel electrode PE may be an electrode in each subpixel SP. For example, the pixel electrode PE may be electrically connected directly or indirectly (via another transistor) to the first node N1 of the corresponding driving transistor DT in each subpixel SP.

The common electrode CE may be an electrode arranged in common to all, or one or more, of a plurality of subpixels SP. For example, a base voltage VSS, which is a type of common driving voltage, may be applied to the common electrode CE through a base voltage line VSSL.

The base voltage VSS may be referred to as a first common voltage, a low common voltage, a low driving voltage, or the like, and the base voltage line VSSL may also be referred to as a first common voltage line, a low common voltage line, a low driving voltage line, or the like.

For example, the pixel electrode PE may be an anode electrode, and the common electrode CE may be a cathode electrode. In another example, the pixel electrode PE may be a cathode electrode and the common electrode CE may be an anode electrode. Hereinafter, for convenience of explanation, discussions are provided based on examples where the pixel electrode PE is an anode electrode and the common electrode CE is a cathode electrode.

The intermediate layer EL may include an emission layer EML and a common intermediate layer EL_COM.

The emission layer EML may be disposed in a light emitting area of each of a plurality of subpixels SP. For example, the emission layer EML may be disposed only in each of a plurality of subpixels SP. In another example, the emission layer EML may be disposed in common in all, or two or more, of a plurality of subpixels SP. In another example, the emission layer EML may be disposed only in a light emitting area. In another example, the emission layer EML may be disposed in both a light emitting area and a non-light emitting area.

The common intermediate layer EL_COM may be disposed in common across all, or two or more, of a plurality of subpixels SP. The common intermediate layer EL_COM may be disposed in common in a plurality of light emitting areas EA and one or more non-light emitting areas.

The common intermediate layer EL_COM may include a first common intermediate layer COM1 and a second common intermediate layer COM2. The first common intermediate layer COM1 may be disposed between the pixel electrode PE and the emission layer EML and may include at least one layer (e.g., an organic layer). The second common intermediate layer COM2 may be disposed between the emission layer EML and the common electrode CE and may include at least one layer (e.g., an organic layer). For example, the first common intermediate layer COM1 may include a hole injection layer HIL, a hole transport layer HTL, and the like. The second common intermediate layer COM2 may include an electron transport layer ETL, an electron injection layer EIL, and the like.

The hole injection layer HIL can inject holes from the pixel electrode PE to the hole transport layer HTL. The hole transport layer HTL can transport holes to the emission layer EML. The electron injection layer EIL can inject electrons from the common electrode CE to the electron transport layer ETL. The electron transport layer ETL can transport electrons to the emission layer EML. To emit light, each light emitting element ED may include a portion in which the corresponding pixel electrode PE, the emission layer EML in the corresponding intermediate layer EL, and the corresponding common electrode CE overlap with each other. Each light emitting element ED may provide a corresponding light emitting area EA. For example, each light emitting area EA may be defined as an area where the corresponding pixel electrode PE, the emission EML of the corresponding intermediate layer EL, and the corresponding common electrode CE overlap with each other.

In one or more aspects, the light emitting element ED may be an organic light emitting diode OLED, an inorganic light emitting diode, a quantum dot light emitting element, a micro light emitting diode, a mini light emitting diode, and the like.

In the example where the light emitting element ED is an organic light emitting diode, the intermediate layer EL of the light emitting element ED may include an organic layer including an organic material.

The scan transistor ST may be turned on or off by a scan signal SC, which is one type of gate signal carried through a scan signal line SCL, which is one type of gate line GL, and may be electrically connected between the second node N2 of the driving transistor DT and a data line DL.

The storage capacitor Cst may be electrically connected between the first node N1 and the second node N2 of the driving transistor DT.

The subpixel circuit SPC may have a 2T(Transistor)1C(Capacitor) structure including two transistors (DT and ST) and one capacitor (Cst) as illustrated in FIG. 4. In one or more aspects, the subpixel circuit SPC may further include one or more transistors or one or more capacitors in the 2T1C structure.

In some embodiments, the storage capacitor Cst, which may be present between the first node N1 and the second node N2 of the driving transistor DT, may be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like). Each of the driving transistor DT and the scan transistor ST may be an n-type transistor or a p-type transistor.

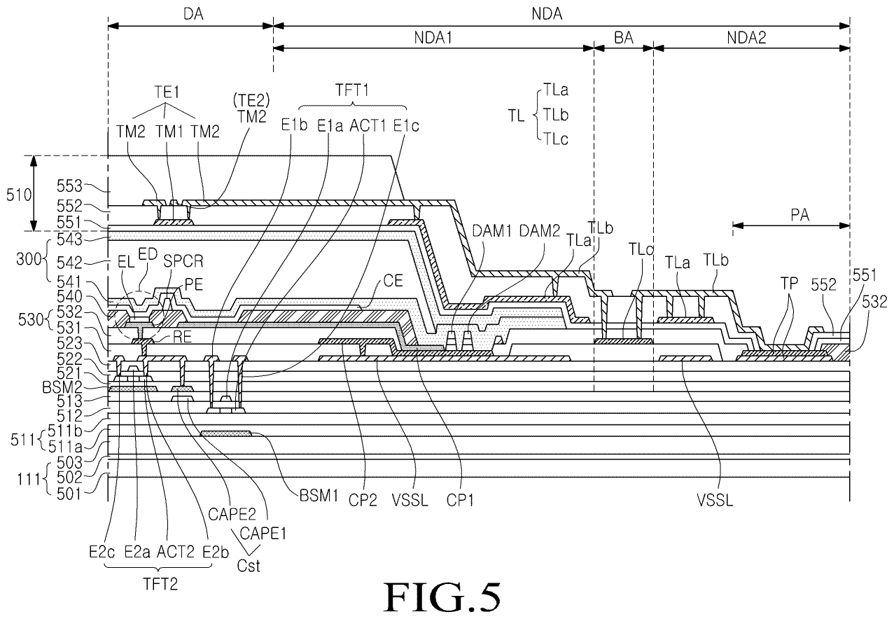

FIG. 5 is an example cross-sectional view of the display panel 110 according to aspects of the present disclosure.

Referring to FIG. 5, in one or more example embodiments, the display panel 110 may include a substrate 111, a transistor part, a light emitting element part, and an encapsulation part, but aspects of the present disclosure are not limited thereto.

The substrate 111 may be formed of a single layer or multiple layers. In an example where the substrate 111 is formed of multiple layers, the substrate 111 may include a first substrate 501, an intermediate substrate layer 502, and a second substrate 503.

The intermediate substrate layer 502 may be located between the first substrate 501 and the second substrate 503. In one or more aspects, each of the first substrate 501 and the second substrate 503 may be a polyimide (PI) layer, but aspects of the present disclosure are not limited thereto.

The intermediate substrate layer 502 may be an inorganic insulating layer, but aspects of the present disclosure are not limited thereto. When electric charges are stored on the first substrate 501, which is a polyimide (PI) layer, the intermediate substrate layer 502 can block the charges from affecting transistors on the second substrate 503 through the second substrate 503, which is a polyimide (PI) layer.

The intermediate substrate layer 502 can block moisture from moving upwardly through the first substrate 501. For example, the intermediate substrate layer 502 may be formed of a single layer of silicon nitride (SiNx) or silicon oxide (SiOx) or multiple layers thereof, or be formed of double layers of silicon dioxide (SiO2) and silicon nitride (SiNx), but aspects of the present disclosure are not limited thereto.

The transistor part may include insulating layers (511, 512, 513, 521, 522, and 523), thin film transistors (TFT1 and TFT2), a storage capacitor Cst, and several electrodes or signal lines, on the substrate 111.

The thin film transistors (TFT1 and TFT2) included in the transistor part may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be the drain electrode or the source electrode. Hereinafter, for convenience of explanation, discussions may be provided based on examples where the first, second, and third electrodes (E1a, E1b, and E1c) are a first gate electrode E1a, a first source electrode E1b, and a first drain electrode E1c, respectively.

The first active layer ACT1 may include a first semiconductor material. For example, the first semiconductor material may include an oxide semiconductor, amorphous silicon, polysilicon, low-temperature polysilicon (LTPS), or the like.

The first thin film transistor TFT1 may be implemented as a p-channel transistor or an n-channel transistor.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions may be provided based on examples where the fourth, fifth, and sixth electrodes (E2a, E2b, and E2c) are a second gate electrode E2a, a second source electrode E2b, and a second drain electrode E2c, respectively.

The second active layer ACT2 may include a second semiconductor material. For example, the second semiconductor material may include an oxide semiconductor, amorphous silicon, polysilicon, or low-temperature polysilicon (LTPS), or the like. The second thin film transistor TFT2 may be implemented as a p-channel transistor or an n-channel transistor.

The types of semiconductor materials of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. For example, the first active layer ACT1 of the first thin film transistor TFT1 and the second active layer ACT2 of the second thin film transistor TFT2 may include a low-temperature polysilicon semiconductor material. In another example, the first active layer ACT1 of the first thin film transistor TFT1 may include a low-temperature polysilicon semiconductor material, and the second active layer ACT2 of the second thin film transistor TFT2 may include an oxide semiconductor material. In another example, the first active layer ACT1 of the first thin film transistor TFT1 may include an oxide semiconductor material, and the second active layer ACT2 of the second thin film transistor TFT2 may include a low-temperature polysilicon semiconductor material.

Transistors disposed in the display area DA may be used as follows.

For example, all of transistors included in each subpixel SP may be implemented as the first thin film transistor TFT1. For example, all of transistors included in each subpixel SP may be implemented as the second thin film transistor TFT2. For example, some of transistors included in each subpixel SP may be implemented as the first thin film transistor TFT1, and the other thereof may be implemented as the second thin film transistor TFT2. For example, each subpixel SP may include at least one first thin film transistor TFT1 and at least one second thin film transistor TFT2.

Some of transistors included in each subpixel SP may be implemented as the first thin film transistor TFT1, and the other thereof may be implemented as the second thin film transistor TFT2.

For example, in each subpixel SP, a corresponding driving transistor DT may be implemented as the first thin film transistor TFT1, and the remaining one or more transistors (e.g., a scan transistor ST, an emission control transistor, and/or the like) except for the driving transistor DT may be implemented as the second thin film transistor TFT2.

For example, in each subpixel SP, a corresponding driving transistor DT may be implemented as the second thin film transistor TFT2, and the remaining one or more transistors (e.g., a scan transistor ST, an emission control transistor, and/or the like) except for the driving transistor DT may be implemented as the first thin film transistor TFT1.

In FIG. 5, the second thin film transistor TFT2 connected to a pixel electrode PE of a light emitting element ED may be a driving transistor DT or a transistor different from the driving transistor DT depending on the configuration of a corresponding subpixel circuit SPC.

For example, in FIG. 5, the second thin film transistor TFT2 connected to the pixel electrode PE of the light emitting element ED may be a light emitting control transistor connected between a driving transistor DT and the light emitting element ED.

Transistors disposed in the non-display area NDA may be used as follows.

For example, the active layers of transistors included in the gate driving circuit 230 of the gate-in-panel (GIP) type may include an oxide semiconductor material. For example, the active layers of transistors included in the gate driving circuit 230 of the gate-in-panel (GIP) type may include a low-temperature polysilicon semiconductor material. For example, among the active layers of transistors included in the gate driving circuit 230 of the gate-in-panel (GIP) type, some active layers may include a low-temperature polysilicon semiconductor material, and other active layers or the remaining active layers may include an oxide semiconductor material.

The second active layer ACT2 of the second thin film transistor TFT2 may be located higher from the substrate 111 than the first active layer ACT1 of the first thin film transistor TFT1.

A first buffer layer 511 may be disposed under the first active layer ACT1 of the first thin film transistor TFT1, and a second buffer layer 521 may be disposed under the second active layer ACT2 of the second thin film transistor TFT2. For example, the first active layer ACT1 of the first thin film transistor TFT1 may be disposed on the first buffer layer 511, and the second active layer ACT2 of the second thin film transistor TFT2 may be disposed on the second buffer layer 521. The second buffer layer 521 may be disposed on the first buffer layer 511.

A storage capacitor Cst may be disposed in several metal layers in the display panel 110. For example, the storage capacitor Cst may include a first capacitor electrode CAPE1 and a second capacitor electrode CAPE2.

The light emitting element part may include a plurality of light emitting elements ED disposed on a planarization layer 530. Each of the plurality of light emitting elements ED may include a pixel electrode PE, an intermediate layer EL, and a common electrode CE.

In one or more aspects, at least one spacer SPCR may be disposed between the intermediate layer EL and a bank 540.

The spacer SPCR may serve to buffer an empty space on the substrate 111 to minimize damage to the display device due to an external impact.

The spacer SPCR may include the same material as the bank 540 and may be formed together with the bank 540.

The encapsulation part may include an encapsulation layer 300 on a plurality of light emitting elements ED The encapsulation layer 300 may be formed of a single layer or a multilayer, but aspects of the present disclosure are not limited thereto.

The encapsulation part can block the penetration of moisture or oxygen, and may be formed across the display area DA and the non-display area NDA.

In addition to the encapsulation layer 300, the encapsulation part may further include at least one dam DAM to prevent a material included in the encapsulation layer 300 from overflowing. For example, in an example where the encapsulation layer 300 includes a first encapsulation layer 541, a second encapsulation layer 542, and a third encapsulation layer 543, and the second encapsulation layer 542 is an organic encapsulation layer including an organic material, the dam DAM may prevent the organic encapsulation layer from overflowing during the process of manufacturing the display panel 110. This is because the organic encapsulation layer may generally include a polymer and have fluidity until a curing process is performed.

Hereinafter, a vertical structure or stack-up structure of the display panel 110 is described in more detail with reference to FIG. 5.

Referring to FIG. 5, the first buffer layer 511 may be disposed on the substrate 111. The first buffer layer 511 may be formed of a single layer or a multilayer, but aspects of the present disclosure are not limited thereto. In an example where the first buffer layer 511 is formed of a multilayer, the first buffer layer 511 may include a lower buffer layer 511a and an upper buffer layer 511b.

The first active layer ACT1 of the first thin film transistor TFT1 may be disposed on the first buffer layer 511. The first active layer ACT1 may include a channel region where a channel is formed, a source connection region on a first side of the channel region, and a drain connection region on a second opposing side of the channel region.

A first gate insulating layer 512 may be disposed on the first active layer ACT1 of the first transistor TFT1. The first gate electrode E1a of the first thin transistor TFT1 may be disposed on the first gate insulating layer 512. A first interlayer insulating layer 513 may be disposed on the first gate electrode E1a of the first thin film transistor TFT1. A metal layer in which the first gate electrode E1a of the first thin film transistor TFT1 is disposed may be referred to as a first gate metal layer.

The second buffer layer 521 may be disposed on the first interlayer insulating layer 513.

The second active layer ACT2 of the second thin film transistor TFT2 may be disposed on the second buffer layer 521. The second active layer ACT2 may include a channel region where a channel is formed, a source connection region on a first side of the channel region, and a drain connection region on a second opposing side of the channel region.

A second gate insulating layer 522 may be disposed on the second active layer ACT2 of the second thin film transistor TFT2. The second gate electrode E2a of the second thin film transistor TFT2 may be disposed on the second gate insulating layer 522. A second interlayer insulating layer 523 may be disposed on the second gate electrode E2a of the second thin film transistor TFT2. The second gate electrode E2a of the second thin film transistor TFT2 may be referred to as a second gate metal layer.

The first source electrode E1b and the first drain electrode E1c of the first thin film transistor TFT1 and the second source electrode E2b and the second drain electrode E2c of the second thin film transistor TFT2 may be disposed on the second interlayer insulating layer 523.

The first source electrode E1b and the first drain electrode E1c of the first thin film transistor TFT1 may be connected to a source connection region and a drain connection region of the first active layer ACT1, respectively, through holes formed in the second interlayer insulating layer 523, the second gate insulating layer 522, the second buffer layer 521, the first interlayer insulating layer 513, and the first gate insulating layer 512.

The second source electrode E2b and the second drain electrode E2c of the second thin film transistor TFT2 may be connected to a source connection region and a drain connection region of the second active layer ACT2, respectively, through holes formed in the second interlayer insulating layer 523 and the second gate insulating layer 522.

The first source electrode E1b and the first drain electrode E1c of the first thin film transistor TFT1, and the second source electrode E2b and the second drain electrode E2c of the second thin film transistor TFT2 may include a first source-drain metal and may be disposed in a first source-drain metal layer.

Referring to FIG. 5, in one or more aspects, the storage capacitor Cst may include the first capacitor electrode CAPE1 and the second capacitor electrode CAPE2. For example, the storage capacitor Cst may include three or more capacitor electrodes, and may include two or more capacitors connected in parallel.

Each of the first capacitor electrode CAPE1 and the second capacitor electrode CAPE2 may be disposed in several metal layers disposed in the display panel 110.

In one or more aspects, the first capacitor electrode CAPE1 may include the same first gate metal as the first gate electrode E1a of the first thin film transistor TFT1 on the first gate insulating layer 512 and may be disposed in the first gate metal layer, but aspects of the present disclosure are not limited thereto. In one or more aspects, the second capacitor electrode CAPE2 may be disposed on the first interlayer insulating layer 513.

The second source electrode E2b of the second transistor TFT2 may be electrically connected to the second capacitor electrode CAPE2 through holes in the second interlayer insulating layer 523, the second gate insulating layer 522, and the second buffer layer 521.

For example, the first thin film transistor TFT1 may be a scanning transistor ST, and the second thin film transistor TFT2 may be a driving transistor DT.

Referring to FIG. 5, the transistor part may further include a first shield pattern BSM1 disposed on the substrate 111. The first shield pattern BSM1 may overlap with the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 511, or may be disposed between the lower buffer layer 511a and the upper buffer layer 511b.

The transistor part may further include a second shield pattern BSM2 disposed on the substrate 111. The second shield pattern BSM2 may overlap with the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first interlayer insulating layer 513 and the second buffer layer 521. The second shield pattern BSM2 may be disposed in the same metal layer as the second capacitor CAPE2, but aspects of the present disclosure are not limited thereto. For example, the second shield pattern BSM2 may be disposed in the same first gate metal layer as the first gate electrode E1a of the first thin film transistor TFT1.

The planarization layer 530 may be disposed on the first thin film transistor TFT1 and the second thin film transistor TFT2, and may be disposed under the light emitting element ED. The planarization layer 530 may be an organic insulating layer including an organic insulating material.

For example, the planarization layer 530 may be formed of a single layer. For example, the planarization layer 530 may be formed of two layers. The planarization layer 530 may include a first planarization layer 531 and a second planarization layer 532. For example, the planarization layer 530 may be formed of three or more layers. However, aspects of the present disclosure are not limited thereto.

Referring to FIG. 5, the first planarization layer 531 may be disposed on the first source electrode E1b and the first drain electrode E1c of the first thin film transistor TFT1 and the second source electrode E2b and the second drain electrode E2c of the second thin film transistor TFT2. For example, the first planarization layer 531 may be disposed on the first thin film transistor TFT1 and the second thin film transistor TFT2. For example, the first planarization layer 531 may be disposed such that it covers both the first thin film transistor TFT1 and the second thin film transistor TFT2.

Referring to FIG. 5, a connection electrode RE may be disposed on the first planarization layer 531. The connection electrode RE may electrically connect the second source electrode E2b of the second thin film transistor TFT2 and the pixel electrode PE.

The connection electrode RE may be electrically connected to the second source electrode E2b of the second thin film transistor TFT2 through a hole of the first planarization layer 531. The second source electrode E2b of the second thin film transistor TFT2 may be electrically connected to the second capacitor electrode CAPE2 of the storage capacitor Cst.

The connection electrode RE may be disposed in a second source-drain metal layer on the first planarization layer 531.

The second planarization layer 532 may be disposed on the connection electrode RE.

Referring to FIG. 5, the light emitting element part may be disposed on the second planarization layer 532. The light emitting element ED may be formed on the second planarization layer 532. The light emitting element ED may include the pixel electrode PE, the intermediate layer EL, and the common electrode CE. A light emitting area of the light emitting element ED may be formed by an area where the pixel electrode PE, the intermediate layer EL, and the common electrode CE overlap and contact each other.

The pixel electrode PE may be disposed on the second planarization layer 532. The pixel electrode PE may be electrically connected to the connection electrode RE through a hole of the second planarization layer 532.

The bank 540 may be disposed on the pixel electrode PE. An opening of the bank 540 may expose a portion of the pixel electrode PE to form a light emitting area. The opening of the bank 540 may overlap with a portion of the pixel electrode PE.

For example, the bank 540 may include a material including a black pigment, or an organic material including a benzocyclobutene resin, a polyimide resin, an acrylic resin, a photosensitive polymer, or the like.

In an example where the bank 540 includes a material including a black pigment or a black dye, the bank 540 may be a black bank. In the example where the bank 540 includes a material including a black pigment or a black dye, the luminance of the display device can be further improved because light from the outside or light reflected from the outside can be blocked.

The intermediate layer EL of the light emitting element ED may be disposed on a portion of the pixel electrode PE and the bank 540. The common electrode CE may be disposed on the intermediate layer EL.

Referring to FIG. 5, the encapsulation part may be disposed on the light emitting element part, and be located on the common electrode CE. The encapsulation part may include an encapsulation layer 300 disposed on the common electrode CE.

The encapsulation layer 300 can prevent moisture or oxygen from penetrating into the light emitting element ED. For example, the encapsulation layer 300 can prevent moisture or oxygen from penetrating into an organic material included in the intermediate layer EL of the light emitting element ED. In one or more aspects, the encapsulation layer 300 may be formed of a single layer or multiple layers, but aspects of the present disclosure are not limited thereto.

For example, the encapsulation layer 300 may include a first encapsulation layer 541, a second encapsulation layer 542, and a third encapsulation layer 543. For example, the first encapsulation layer 541 and the third encapsulation layer 543 may include an inorganic material, and the second encapsulation layer 542 may include an organic material. However, aspects of the present disclosure are not limited thereto.

In one or more aspects, a touch sensor may be embedded in the display panel 110. In this implementation, the display panel 110 may include a touch sensor layer 510 disposed on the encapsulation layer 300 and including a touch sensor.

Referring to FIG. 5, the touch sensor layer 510 may include a plurality of touch electrodes TE serving as the touch sensor, and include at least one touch metal layer for forming the plurality of touch electrodes TE.

For example, to form the plurality of touch electrodes TE, the touch sensor layer 510 may include a first touch metal layer in which a plurality of first touch metals TM1 are disposed, and a second touch metal layer in which a plurality of second touch metals TM2 are disposed. In this implementation, the touch sensor layer 510 may further include a touch interlayer insulating layer 552 disposed between the first touch metal layer and the second touch metal layer.

For example, one of the first touch metal layer and the second touch metal layer may be a sensor metal layer, and the other may be a bridge metal layer.

For example, the first touch metal layer may be a bridge metal layer, and the second touch metal layer may be a sensor metal layer. In this implementation, the plurality of second touch metals TM2 disposed in the second touch metal layer may be sensor metals forming the touch sensor, and the plurality of first touch metals TM1 disposed in the first touch metal layer may be bridge metals electrically connecting the plurality of second touch metals TM2, which are the sensor metals. For example, two or more second touch metals TM2 and at least one first touch metal TM1 may form one first touch electrode TE1. In this implementation, the two or more second touch electrodes TE2 may be electrically connected by at least one first touch metal TM1.

In another example, the first touch metal layer may be a sensor metal layer, and the second touch metal layer may be a bridge metal layer. In this implementation, the plurality of first touch metals TM1 disposed in the first touch metal layer may be sensor metals forming the touch sensor, and the plurality of second touch metals TM2 disposed in the second touch metal layer may be bridge metals electrically connecting the plurality of first touch metals TM1, which are the sensor metals.

In another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this implementation, the plurality of first touch metals TM1 disposed in the first touch metal layer may include sensor metals and bridge metals, and the plurality of second touch metals TM2 disposed in the second touch metal layer may include sensor metals and bridge metals.

Referring to FIG. 5, the touch sensor layer 510 may further include a touch buffer layer 551 disposed on the encapsulation layer 300. The touch buffer layer 551 may be disposed between the encapsulation layer 300 and the touch metal layer. For example, the first touch metal layer may be disposed on the touch buffer layer 551, and the touch interlayer insulating layer 552 may be disposed on the first touch metal layer.

Referring to FIG. 5, the touch sensor layer 510 may further include a touch protection layer 553 disposed such that the touch protection layer 553 covers the touch metal layers. For example, the touch protection layer 553 may be disposed on the second touch metal layer.

For example, the touch buffer layer 551 may be an inorganic layer including an inorganic insulating material or an organic layer including an organic insulating material. The touch interlayer insulating layer 552 may be an inorganic layer including an inorganic insulating material or an organic layer including an organic insulating material. The touch protection layer 553 may be an inorganic layer including an inorganic insulating material or an organic layer including an organic insulating material.

For example, at least one of the touch buffer layer 551 and the touch interlayer insulating layer 552 may be disposed to extend from the display area DA to the non-display area NDA. The touch protection layer 553 may be disposed to extend from the display area DA to the non-display area NDA.

A touch routing line TL may electrically connect a touch electrode TE and a touch pad TP. The touch routing line TL may be formed by at least one of the first touch metal TM1 and the second touch metal TM2.

For example, the touch routing line TL may be formed by the first touch metal TM1. For example, the touch routing line TL may be formed by the second touch metal TM2. For example, the touch routing line TL may be formed by the first touch metal TM1 and the second touch metal TM2. In an example where one touch routing line TL is formed by the first touch metal TM1 and the second touch metal TM2, the first touch metal TM1 and the second touch metal TM2 included in the touch routing line TL may be electrically connected through a hole in the insulating layer 552.

For example, one touch routing line TL may include a plurality of line portions, and each of the plurality of line portions may be a single line portion or a double line portion. For example, the single line portion may be a line portion with one signal path, and the double line portion may be a line portion with two signal paths connected in parallel.

The touch routing line TL may extend along an inclined surface of the encapsulation layer 300, extend over an upper portion of at least one dam (DAM1 and/or DAM2), and reach a touch pad TP.

The touch buffer layer 551 may have an opening to expose at least a portion of the touch pad TP. The touch routing line TL may be electrically connected to the touch pad TP through the opening of the touch buffer layer 551. The touch interlayer insulating layer 552 may be disposed on a portion of the touch routing line TL and may extend to an area where the touch pad TP is disposed. The touch protection layer 553 may be disposed only in the display area DA, or may extend to the non-display area NDA and be disposed on the touch routing line TL. In one or more aspects, the touch protection layer 553 may extend further to an upper portion of the touch pad TP.

Each of a plurality of touch electrodes TE may be a mesh-type electrode configured to have a mesh and having a plurality of openings. In this implementation, each of the plurality of touch electrodes TE may include at least one second touch metal TM2. However, aspects of the present disclosure are not limited thereto.

For example, the plurality of touch electrodes TE may include at least one first touch electrode TE1 and at least one second touch electrode TE2. In an example where the first touch metal layer is a bridge metal layer and the second touch metal layer is a sensor metal layer, two or more second touch metals TM2 included in a first touch electrode TE1, which is the touch sensor, may be electrically connected through at least one first touch metal TM1, which is the bridge metal. For example, two second touch metals TM2 spaced apart from each other may be electrically connected by a first touch metal TM1 to form one first touch electrode TE1.

Referring to FIG. 5, the plurality of first touch metals TM1 and the plurality of second touch metals TM2 may be disposed not to overlap with the light emitting element ED. The plurality of first touch metals TM1 and the plurality of second touch metals TM2 may overlap with the bank 540. According to these configurations, the display panel 110 can provide an advantage of improving the emission efficiency of the light emitting element ED.

Referring to FIG. 5, the touch routing line TL may connect the touch pad TP disposed in a pad area PA of a second non-display area NDA2 and the first touch electrode TE1 disposed in the display area DA. In this implementation, the touch routing line TL may be disposed across the second non-display area NDA2, a bending area BA, and a first non-display area NDA1.

The touch routing line TL may include a first line portion TLa, a second line portion TLb, and a third line portion TLc. For example, the touch routing line TL may include the first line portion TLa and the second line portion TLb disposed in the first non-display area NDA1 and the second non-display area NDA2, and the third line portion TLc disposed in the bending area BA. The third line portion TLc may connect two first line portions TLb or the first line portion TLa and the second line portion TLb.

The first line portion TLa of the touch routing line TL may be a single line portion.

The first line portion TLa of the touch routing line TL may be disposed to extend along an inclined surface of the encapsulation layer 300, and further extend over at least one dam (DAM1 and/or DAM2).

For example, the first line portion TLa of the touch routing line TL may be connected to the third line portion TLc of the touch routing line TL through at least one of the first touch metal layer and the second touch metal layer.

The second line portion TLb of the touch routing line TL may include at least one of the first touch metal layer on which the first touch metal TM1 is disposed and the second touch metal layer on which the second touch metal TM2 is disposed.

For example, the second line portion TLb of the touch routing line TL may be formed by the second touch metal layer. For another example, the second line portion TLb of the touch routing line TL may be formed by an electrical connection of the first touch metal layer and the second touch metal layer.

For example, the second line portion TLb of the touch routing line TL may be electrically connected to the touch pad TP through a contact hole (opening) through the second planarization layer 532, the touch buffer layer 551, and the touch interlayer insulation layer 552.

For example, the third line portion TLc of the touch routing line TL may be connected to the second line portion TLb of the touch routing line TL.

The third line portion TLc of the touch routing line TL may include a metal layer different from the first to third touch metal layers in which the first to third touch metals (TM1, TM2, and TM3) are disposed. For example, the metal layer included in the third line portion TLc of the touch routing line TL may be the same as a metal layer in which one or more electrodes or lines for display driving are disposed. For example, the metal layer included in the third line portion TLc of the touch routing line TL may include a metal layer in which the pixel electrode PE is disposed, but aspects of the present disclosure are not limited thereto.

The touch pad TP may be electrically connected to the second line portion TLb of the touch routing line TL and may include a metal layer different from the first to third touch metal layers. For example, the metal layer included in the touch pad TP may be the same as a metal layer in which one or more electrodes or lines for display driving are disposed. For example, the metal layer included in the touch pad TP may include a metal layer in which the pixel electrode PE is disposed, but aspects of the present disclosure are not limited thereto.

The common electrode CE may be an electrode disposed in common to all, or one or more, of a plurality of subpixels SP. For example, a base voltage VSS, which is a type of common driving voltage, may be applied to the common electrode CE through a base voltage line VSSL. The base voltage line VSSL may be referred to as a first common voltage line.

Referring to FIG. 5, in one or more aspects, the display panel 110 may further include a connection pattern for connecting the common electrode CE and the first common voltage line VSSL.

The connection pattern may include a first connection pattern CP1 and a second connection pattern CP2.

For example, the first connection pattern CP1 may connect the common electrode CE and the second connection pattern CP2, and the second connection pattern CP2 may connect the first connection pattern CP1 and the first common voltage line VSSL, but aspects of the present disclosure are not limited thereto.

For example, the first connection pattern CP1 may include the same material as the pixel electrode PE. The second connection pattern CP2 may include the same material as the connection electrode RE.

Hereinafter, a stackup structure of the display panel 110 in the non-display area is discussed.

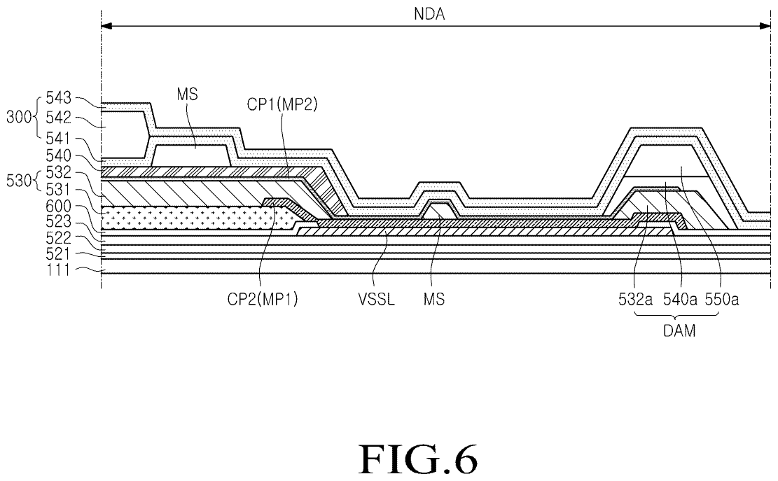

FIG. 6 is an example simplified cross-sectional view of the display panel 110 according to aspects of the present disclosure. Hereinafter, discussions for the stack-up configurations of FIG. 6 are provided in connection with the stack-up configurations shown in FIG. 5, and discussions for some layers that are the same, or substantially the same, as some of layers in the configurations of FIG. 5 may be omitted.

A second buffer layer 521, a second gate insulating layer 522, and a second interlayer insulating layer 523 may be disposed on the substrate 111. The second buffer layer 521, the second gate insulating layer 522, and the second interlayer insulating layer 523 may be insulating layers on the substrate 111 included in a transistor part.

A passivation layer 600 may be further disposed on the second interlayer insulating layer 523. The passivation layer 600 may protect a second source-drain metal layer in which a connection electrode RE is disposed.

A planarization layer 530 may be disposed on the passivation layer 600, and the planarization layer 530 may include a first planarization layer 531 and a second planarization layer 532.

A connection pattern may connect a common electrode CE and a first common voltage line VSSL, which is a type of common voltage line. The connection pattern may include a first connection pattern CP1 and a second connection pattern CP2. For example, the first connection pattern CP1 may connect the common electrode CE and the second connection pattern CP2, and the second connection pattern CP2 may connect the first connection pattern CP1 and the first common voltage line VSSL.

The second connection pattern CP2 may be disposed in a metal layer between the first planarization layer 531 and the second planarization layer 532. Hereinafter, the second connection pattern CP2 may be referred to as a first metal pattern MP1.

The first connection pattern CP1 may be disposed on the second planarization layer 532. The first connection pattern (CP1) may include the same material as a pixel electrode PE. Hereinafter, the first connection pattern CP1 may be referred to as a second metal pattern MP2.

A bank 540 and an encapsulation layer 300 may be disposed on the second metal pattern MP2.

In one or more aspects, the display device 100 may include at least one dam DAM disposed in an outer edge of the display panel 110 to prevent overflow of a portion of the encapsulation layer 300 that may occur during the process of manufacturing the display panel 110.

In one or more aspects, the display device 100 may further include at least one stopper MS disposed between the second encapsulation layer 542 and the dam DAM to more effectively prevent overflow of a portion of the encapsulation layer 300. The stopper MS may also be referred to as a mid-stopper MS. The stopper MS may perform the same function as the dam.

For example, when the second encapsulation layer 542 among layers included in the encapsulation layer 300 includes an organic material, the second encapsulation layer 542 may overflow during the process of manufacturing the display panel 110. When the overflowed organic material reaches the pad area PA in the non-display area NDA, an electrical contact in the pad area PA may not be made due to the overflowed organic material, which may cause a failure in display driving or touch driving and/or a failure in light emitting inspection, and may also allow the display panel 110 to be vulnerable to the penetration of moisture. Therefore, the dam DAM and the mid-stopper MS may be disposed to prevent overflow of the encapsulation layer including an organic material.

The dam DAM and the mid-stopper MS may be disposed on the second interlayer insulating layer 523.

The dam DAM may include a first layer 532a, a second layer 540a, and a third layer 550a, but aspects of the present disclosure are not limited thereto. The first layer 532a may be located under the second layer 540a, and the second layer 540a may be located under the third layer 550a. In one or more aspects, each layer of the dam DAM may include the same material as at least a portion of the planarization layer 530, the bank 540, and the spacer SPCR.

For example, the first layer 532a of the dam DAM may include the same material as the second planarization layer 532, the second layer 540a of the dam DAM may include the same material as the bank 540, and the third layer 550a of the dam DAM may include the same material as the spacer SPCR. However, aspects of the present disclosure are not limited thereto.

The mid-stopper MS and the dam DAM can prevent a defect of the display device 100 in which the second encapsulation layer 542 including an organic material among layers included in the encapsulation layer 300 overflows beyond the dam DAM. Thus, the mid-stopper MS may be used for preventing overflow of a portion of the encapsulation layer 300, in a similar manner to the function of the dam DAM. In this sense, the mid-stopper MS may be a type of dam DAM.

For example, mid-stoppers MS disposed in the display panel 110 may include a mid-stopper MS disposed on the bank 540 on the planarization layer 530 and located close to an edge of the second encapsulation layer 542, and a mid-stopper MS located in an outward area from the bank 540.

The mid-stopper MS disposed on the bank 540 on the planarization layer 530 and located close to the edge of the second encapsulation layer 542 may include the same material as the spacer SPCR on the bank 540, which may mean that this mid-stopper MS includes a material of the bank 540.

The mid-stopper MS located in the outward area from the bank 540 may include the same material as the planarization layer 530.

The mid-stoppers MS may be structures for preventing overflow of a portion of the encapsulation layer 300 in a similar manner to the function of the dam DAM, and a height from the lower surface of the substrate 111 to an uppermost portion of the mid-stopper MS closest to the dam DAM may be less than a height from the lower surface of the substrate 111 to the uppermost portion of the dam DAM. However, aspects of the present disclosure are not limited thereto.

The first encapsulation layer 541 and the third encapsulation layer 543 may cover all of an upper portion of the dam DAM. In this configuration, the first encapsulation layer 541 and the third encapsulation layer 543 may be inorganic encapsulation layers. Hereinafter, the first encapsulation layer 541 may be referred to as a first inorganic encapsulation layer, and the third encapsulation layer 543 may be referred to as a second inorganic encapsulation layer.

The first inorganic encapsulation layer 541 and the second inorganic encapsulation layer 543 may be disposed on an inner side surface, an upper surface, and an outer side surface of the dam DAM.

In one or more aspects, as described above, the display panel 110 may include the connection pattern for connecting the first common voltage line VSSL to which a common voltage is applied, and the common electrode CE.

The connection pattern may include the first connection pattern CP1 and the second connection pattern CP2.

The first connection pattern CP1 may connect the common electrode CE and the second connection pattern CP2, and the second connection pattern CP2 may connect the first connection pattern CP1 and the first common voltage line VSSL.

The first connection pattern CP1 may be referred to as the second metal pattern MP2, and the second connection pattern may be referred to as the first metal pattern MP1.

The dam DAM may be disposed to overlap with the first common voltage line VSSL, the first metal pattern MP1, and the second metal pattern MP2. The first metal pattern MP1 may include the same material as the connection electrode RE connecting a first source electrode E1b and/or a first drain electrode E1c of a transistor and a pixel electrode PE. For example, the first metal pattern MP1 may be disposed in a second source-drain metal layer. The second metal pattern MP2 may include the same metal as the pixel electrode PE.

The planarization layer 530 may include the first planarization layer 531 and the second planarization layer 532, and the first metal pattern MP1 may be disposed in a metal layer between the first planarization layer 531 and the second planarization layer 532.

The second metal pattern MP2 may be disposed on the second planarization layer 532 and extend to an outward area from the second planarization layer 532.

The first common voltage line VSSL, which is a type of common voltage line, may be a line for applying a common voltage to a common electrode CE of a light emitting element ED in each subpixel SP. In addition, the first common voltage line VSSL may be disposed in a metal layer between the substrate 111 and the first planarization layer 531 and may be electrically connected to the first metal pattern MP1.

The mid-stopper MS may help prevent overflow of a portion of the encapsulation layer 300 including an organic material, but the stackup structure of the mid-stopper MS (e.g., an upper portion of the mid-stopper MS) or a stackup structure located on the mid-stopper MS may be damaged during the process of manufacturing the display panel 110.

The inventors of the present disclosure have discovered a phenomenon in which moisture flows in a disconnected second metal pattern MP2 through a gap during a reliability evaluation process and penetrates into a display area DA, and thereby, a light emitting element does not operate normally, resulting in dark spots or bright spots appearing on a display panel. The inventors have analyzed the cause of this phenomenon, and found that this is related to the curing process that is performed during the manufacturing of a mid-stopper and the display panel and resulting outgassing phenomenon.

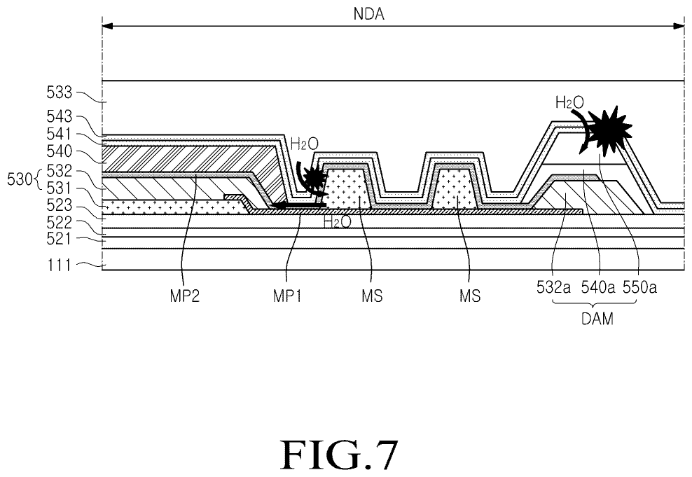

FIG. 7 illustrates example moisture penetration that may occur due to damage to a stackup structure of the display panel 110. Discussions for some layers that are the same, or substantially the same, as some of layers in the configurations of FIGS. 5 and 6 may be omitted.

When the mid-stopper MS includes the same organic material as the planarization layer 530, residual gas remaining in the mid-stopper MS after a mid-stopper curing process may be released thereafter, and thereby, the second metal pattern MP2 may be damaged.

Since the second metal pattern MP2 is deposited thinner than the first metal pattern MP1, the second metal pattern MP2 may be more easily disconnected or damaged by gas release than the first metal pattern MP1.

The first inorganic encapsulation layer 541 and the second inorganic encapsulation layer 543 thereon may have uneven surfaces due to the disconnected second metal pattern MP2, and may also be vulnerable to the penetration of moisture due to the disconnected area of the second metal pattern MP2.

The damage to the stackup structure due to the outgassing described above may occur not only in the mid-stopper MS but also in the dam DAM.

Since the second metal pattern MP2 is formed by the extending of the first connection pattern CP1 including the same material as a pixel electrode PE in the display area DA, even when moisture penetration occurs in the non-display area NDA, the moisture may penetrate into the display area DA along the second metal pattern MP2.

If moisture penetrates into the display area DA, a corresponding light emitting element ED may be damaged and may no longer emit light, which may appear as a dark spot on the display panel 110.

Therefore, the inventors of the present disclosure have designed a structure to effectively prevent overflow of the second encapsulation layer 542 while preventing damage to the stackup structure of the display panel 110 and occurrence of dark spots caused during the process of manufacturing the mid-stopper MS and the dam DAM.

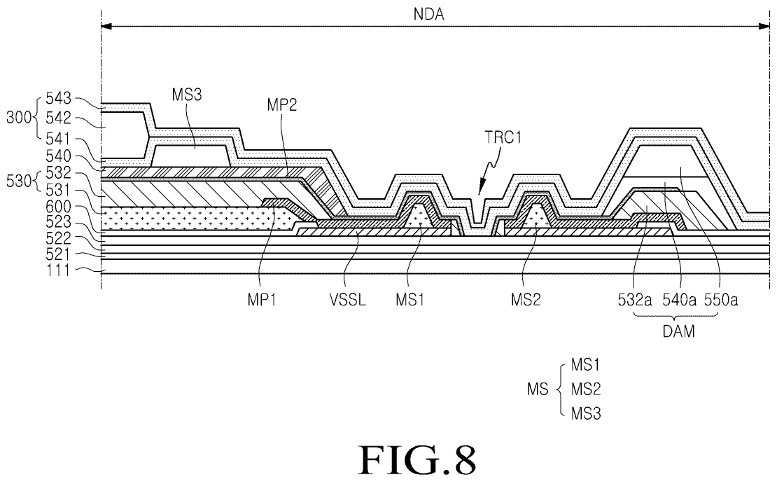

Hereinafter, mid stoppers MS, stackup structures on the mid-stoppers MS, and a trench located between the mid-stoppers MS will be described in detail with reference to FIGS. 8 to 11.

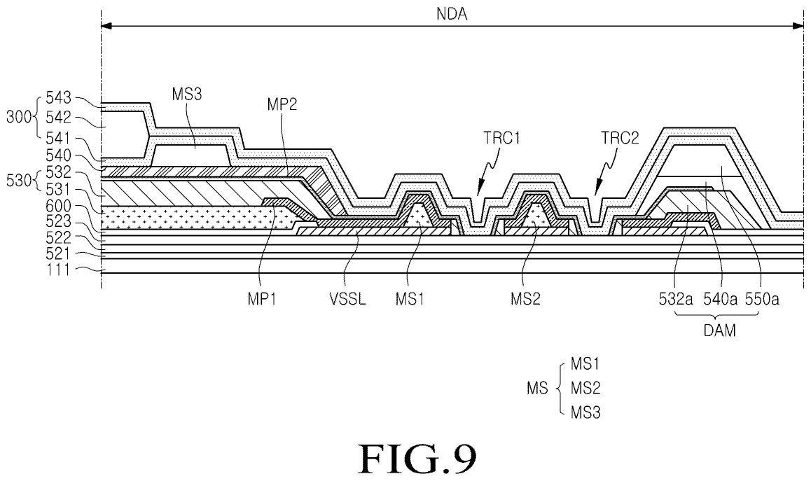

FIGS. 8 and 9 are example simplified cross-sectional views of the display panel 110 according to aspects of the present disclosure. The illustrations of FIGS. 8 and 9 are discussed along with the illustration of FIG. 5. Discussions for some layers that are the same, or substantially the same, as some of layers in the configurations of FIGS. 5 and 6 may be omitted.

In one or more example embodiments, the display panel 110 may include a plurality of mid-stoppers MS in the non-display area NDA.

The mid-stoppers MS may include a first mid-stopper MS1, a second mid-stopper MS2, and a third mid-stopper MS3.

In this configuration, the first mid-stopper MS1 and the second mid-stopper MS2 may include the same material as the planarization layer 530, and the third mid-stopper MS3 may partially overlap with the second encapsulation layer 542 and include the same material as the spacer SPCR. For example, an edge of the third mid-stopper MS3 and an edge of the second encapsulation layer 542 may overlap with each other.

The first mid-stopper MS1 and the second mid-stopper MS2 may be located in an outward area from the planarization layer 530, and the third mid-stopper MS3 may be located on the planarization layer 530. The second mid-stopper MS2 may be located in an outward area from the first mid-stopper MS1.

The encapsulation layer 300 may be disposed on the bank 540, and the encapsulation layer 300 may include the first encapsulation layer 541, the second encapsulation layer 542, and the third encapsulation layer 543. The second encapsulation layer 542 may be disposed on the first encapsulation layer 541, and the third encapsulation layer 543 may be disposed on the second encapsulation layer 542.

Hereinafter, the first encapsulation layer 541 may be referred to as a first inorganic encapsulation layer, the second encapsulation layer 542 may be referred to as an organic encapsulation layer, and the third encapsulation layer 543 may be referred to as a second inorganic encapsulation layer.

The third mid-stopper MS3 may overlap with a boundary of the organic encapsulation layer 542 and be disposed further outwardly than an area where an edge of the organic encapsulation layer 542 is disposed.

At least one of the first inorganic encapsulation layer 541 and the second inorganic encapsulation layer 543 may be disposed to extend further outwardly than the organic encapsulation layer 542.

A first trench TRC1 may be located between the first mid-stopper MS1 and the second mid-stopper MS2. The first mid-stopper MS1 may be located in an inward area from the first trench TRC1, and the second mid-stopper MS2 may be located in outward area from the first trench TRC1.

At least one of the first inorganic encapsulation layer 541 and the second inorganic encapsulation layer 543 may be disposed to run across the first trench TRC1 without being disconnected in the first trench TRC1. For example, at least one of the first inorganic encapsulation layer 541 and the second inorganic encapsulation layer 543 may be disposed on the first mid-stopper MS1 and the second mid-stopper MS2 and be disposed to extend to an outward area from the second mid-stopper MS2.

For example, at least one of the first inorganic encapsulation layer 541 and the second inorganic encapsulation layer 543 may be disposed on the third mid-stopper MS3 and be disposed to extend to an outward area from the third mid-stopper MS3.

When the organic encapsulation layer 542 reaches a pad area located in an outer edge of the non-display area NDA, an electrical contact in the pad area may not be made due to the overflowed organic material, which may cause a failure in display driving or touch driving and/or a failure in light emitting inspection, and may also allow the display panel 110 to be vulnerable to the penetration of moisture. The display panel 110 according to aspects of the present disclosure can provide, by applying both the mid stoppers MS and the trench, an advantage of preventing overflow of the organic encapsulation layer 542 that may occur during the process of manufacturing the display panel 110.

In a plan view for the illustration of FIG. 8, the first mid-stopper MS1 may be located at an area outside of the planarization layer 530 and surround the display area DA, and the second mid-stopper MS2 may be disposed to be spaced apart from the first mid-stopper MS1. The first trench TRC1 may be located between the first mid-stopper MS1 and the second mid-stopper MS2.

A first metal pattern MP1 may be disposed on the first mid-stopper MS1 and the second mid-stopper MS2, and a second metal pattern MP2 may be disposed on the first metal pattern MP1.

In this configuration, the first metal pattern MP1 may be disposed on all of an inner side surface, an upper surface, and an outer side surface of the first mid-stopper MS1, and may also be disposed on all of an inner side surface, an upper surface, and an outer side surface of the second mid-stopper MS2. For example, the first metal pattern MP1 may be disposed such that it covers the first mid-stopper MS1 and the second mid-stopper MS2.

The first metal pattern MP1 may be a second connection pattern CP2, which is a type of connection pattern connecting a common electrode CE and a first common voltage line VSSL, which is a type of common voltage line, and may connect the first common voltage line VSSL and a first connection pattern CP1. The first metal pattern MP1 may include the same material as a connection electrode connecting the source electrode or drain electrode of a transistor and a pixel electrode.

The second metal pattern MP2 may be the first connection pattern CP1, which is also a type of connection pattern, and may electrically connect the common electrode CE and the second connection pattern CP2. The second metal pattern MP2 may include the same material as the pixel electrode PE.

That is, among metal patterns disposed on the first mid-stopper MS1 and the second mid-stopper MS2 and disconnected at the trench TR, portions thereof disposed on the first mid-stopper MS1 may be said to be electrically connected to the common electrode CE.

The first metal pattern MP1 may be thicker than the second metal pattern MP2 including the same material as the pixel electrode PE.

Therefore, compared to an example where only the second metal pattern MP2 is disposed to cover the mid-stoppers MS, an example where the first metal pattern MP1 is disposed to cover the mid-stoppers MS before the second metal pattern MP2 is disposed can minimize damage to the second metal pattern MP2 and an associated stackup structure due to outgassing by covering the second metal pattern MP2 and the associated stack structure with the thick metal patterns, even when the outgassing is generated in the first mid-stopper MS1 and the second mid-stopper MS2 including the same material as the planarization layer 530.

In one or more aspects, the first metal pattern MP1 and the second metal pattern MP2 disposed on the first mid-stopper MS1 and the second mid-stopper MS2 may be disconnected at the first trench TRC1.

As the first metal pattern MP1 and the second metal pattern MP2 are disconnected between the first mid-stopper MS1 and the second mid-stopper MS2, even when damage to the associated stackup structure occurs in an outward area from the first trench TRC, moisture penetrated by the damage to the associated stack structure can be prevented from reaching the display area DA.

In one or more aspects, the second metal pattern MP2 may be disposed on the first metal pattern MP1 at an inward location from the first trench TRC1, and extend to an outer side surface of the first metal pattern MP1 at an inward location from the first trench TRC1, be disposed on the first metal pattern MP1 at an outward location from the first trench TRC, and extend to an inner side surface of the first metal pattern MP1 at an outward location from the first trench TRC1.

The planarization layer 530 may include the first planarization layer 531 and the second planarization layer 532 disposed on the first planarization layer 531, and the first metal pattern MP1 may be disposed on a metal layer between the first planarization layer 531 and the second planarization layer 532. The second metal pattern MP2 may be disposed on the second planarization layer 532.

Therefore, considering the stackup structure in which the first metal pattern MP1 disposed between the first planarization layer 531 and the second planarization layer 532 covers the first mid-stopper MS1 and the second mid-stopper MS2, the first mid-stopper MS1 and the second mid-stopper MS2 may include the same material as the first planarization layer 531.

The first metal pattern MP1 may be disposed to extend to an outer edge, or an area adjacent to the outer edge, of the first planarization layer 531, and the second metal pattern MP2 may be disposed to extend to an outer edge, or an area adjacent to the outer edge, of the second planarization layer 532.

The first common voltage line VSSL, which is a type of common voltage line to which a common voltage is applied, may be disposed under the first mid-stopper MS1 and the second mid-stopper MS2.

The first common voltage line VSSL, which is a type of common voltage line, may be disconnected between the first mid-stopper MS1 and the second mid-stopper MS2 by the first trench TRC1, which may be similar to corresponding configurations of the first connection pattern CP1 and the second connection pattern CP2.

An organic layer may be disposed between the first metal pattern MP1 and the second metal pattern MP2 at an inward location from the first trench TRC1. In this implementation, the organic layer may include the same material as the second planarization layer 531.

In one or more aspects, the display device may include a dam DAM located further outwardly than the second mid-stopper MS2.

In plan views for the illustrations of FIGS. 8 and 9, the dam DAM may surround the second mid-stopper MS2 and be spaced apart from the second mid-stopper MS2.

The dam DAM can prevent overflow of the organic encapsulation layer 542 during the process of manufacturing the display panel 110 or the display device 100 in a similar manner to the function of the mid stopper MS.

The dam DAM may include a first layer 532a, a second layer 540a, and a third layer 550a, but aspects of the present disclosure are not limited thereto. The first layer 532a may be located under the second layer 540a, and the second layer 540a may be located under the third layer 550a. In one or more aspects, each layer of the dam DAM may include the same material as at least a portion of the planarization layer 530, the bank 540, and the spacer SPCR.

For example, the first layer 532a of the dam DAM may include the same material as the second planarization layer 532, the second layer 540a of the dam DAM may include the same material as the bank 540, and the third layer 550a of the dam DAM may include the same material as the spacer SPCR.

The height of the dam DAM may be greater than the heights of the first mid-stopper MS1 and the second mid-stopper MS2. For example, a height from the lower surface of the substrate 111 to an uppermost portion of the dam DAM may be greater than heights from the lower surface of the substrate 111 to respective uppermost portions of the first mid-stopper MS1 and/or the second mid-stopper MS2.

At least one of the first inorganic encapsulating layer 541 and the second inorganic encapsulating layer 543 may be disposed on the dam DAM and extend to an outward area from the dam DAM.

At least one of the first metal pattern MP1, the second metal pattern MP2, and the first common voltage line VSSL may extend under a lower portion, or between portions, of the dam DAM.

In one or more aspects, to more effectively prevent the penetration of moisture that may occur when the organic encapsulation layer 542 overflows and an associated stackup structure is damaged, a trench may be further disposed between the second mid-stopper MS2 and the dam DAM. In this implementation, the trench between the second mid-stopper MS2 and the dam DAM may be referred to as a second trench TRC2.

The first metal pattern MP1 and the second metal pattern MP2 disposed on the first mid-stopper MS1 and the second mid-stopper MS2 may be disconnected at the second trench TRC2, which may be similar to corresponding configurations in the first trench TRC1.

The first common voltage line VSSL may be disconnected between the second mid-stopper MS2 and the dam DAM by the second trench TRC2, which may be similar to corresponding configurations of the first connection pattern CP1 and the second connection pattern CP2.

At least one of the first inorganic encapsulation layer 541 and the second inorganic encapsulation layer 543 may be disposed to extend beyond an upper portion of the dam DAM and to an area located outwardly from the dam DAM without being disconnected at the second trench TRC2.

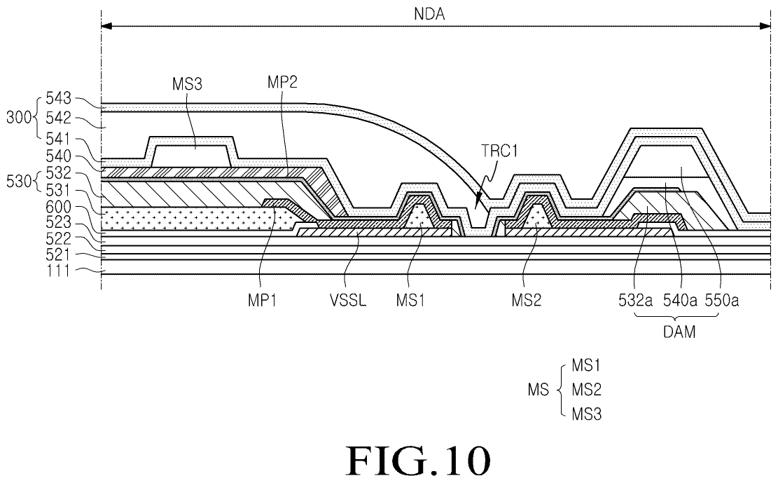

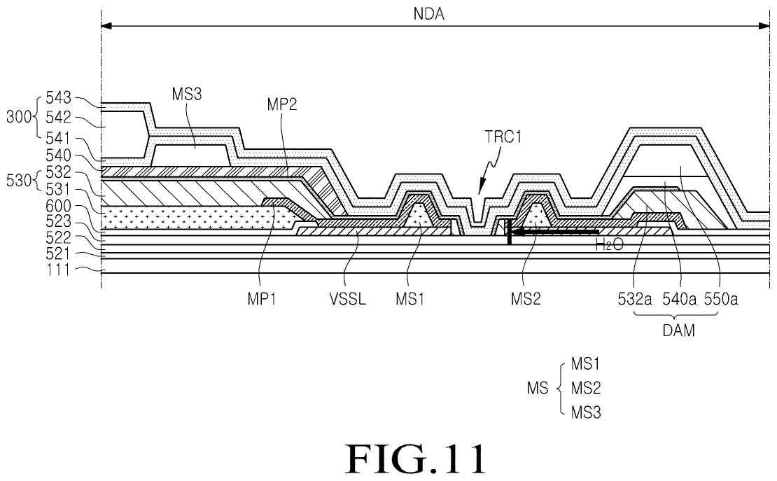

Hereinafter, technical effects according to aspects, examples, embodiments of the present disclosure will be described in detail with reference to FIGS. 10 and 11.

FIG. 10 illustrates an example where the first trench TRC1 serves to prevent overflow of the organic encapsulation layer 542 in the display device 100 according to aspects of the present disclosure. The illustrations of FIGS. 10 and 11 are discussed along with the illustration of FIG. 9.

The dam DAM and the mid-stopper MS may be disposed to prevent overflow of the organic encapsulation layer 542.

The third mid-stopper MS3, which may overlap with the organic encapsulation layer 542 in a boundary therebetween, can firstly prevent overflow of the organic encapsulation layer 542. However, when the degree of overflow is severe, the organic encapsulation layer 542 may overflow beyond the third mid-stopper MS3.

Even when the organic encapsulation layer 542 overflows beyond the third mid-stopper MS3 and the first mid-stopper MS1, the display device according to aspects of the present disclosure can prevent the organic encapsulation layer 542 from overflowing beyond the second mid-stopper MS2 and the dam DAM by the valley formed through the first trench TRC1.

When the second trench TRC2 is disposed between the second mid-stopper MS2 and the dam DAM, even when the organic encapsulation layer 542 overflows beyond the second mid-stopper MS2, the valley formed through the second trench TRC2 can prevent the organic encapsulation layer 542 from overflowing to an outward area from the dam DAM.

FIG. 11 illustrates an example where moisture penetration is blocked in the display device 100 according to aspects of the present disclosure.

In one or more aspects, the display device 100 can be configured with a stackup structure that is robust against outgassing that may occur during the process of manufacturing the display panel 110 by disposing the first metal pattern MP1 on respective inner side surfaces, upper surfaces, and outer side surfaces of the first mid-stopper MS1 and the second mid-stopper MS2.

Although the second metal pattern MP2, which may include the same material as a pixel electrode PE, may be damaged by outgassing, since the first metal pattern MP1 may include the same material as a connecting electrode connecting the source electrode or drain electrode of a transistor and the pixel electrode and be deposited thicker than the second metal pattern MP2, even if outgassing occurs in the first mid-stopper MS1 and/or the second mid-stopper MS2 under high temperature conditions, the display device 100 can prevent the occurrence of cracks in the second metal pattern MP2 by the configuration in which the first mid-stopper MS1 and the second mid-stopper MS2 is covered by the first metal pattern MP1.

Further, through these implementations, the first inorganic encapsulation layer 541 and/or the third inorganic encapsulation layer 543 may be normally deposited on the first mid-stopper MS1 and the second mid-stopper MS2.

In addition, referring to FIG. 11, even when damage to the mid-stopper MS and the dam DAM and an outer area occurs due to undesired substances, such as moisture, and the like or cracks, the display device 100 can block a path through which moisture coming from the outside can enter the inside of the display area DA by the structure where the first metal pattern MP1 and the second metal pattern MP2 are cut off at a portion of the non-display area NDA by the first trench TRC1.

When the second trench TRC2 is disposed between the second mid-stopper MS2 and the dam DAM, even when damage to the second mid-stopper MS2, the dam DAM, and an outer area occurs due to undesired substances such as moisture, and the like or cracks, the display device 100 can block a path through which moisture coming from the outside can enter the inside of the display area DA by the structure where the first metal pattern MP1 and the second metal pattern MP2 are cut off at a portion of the non-display area NDA by the second trench TRC2,

According to the examples, aspects, and embodiments described herein, the display device 100 can provide advantages of minimizing damage to a stackup structure due to overflow of an organic encapsulation layer or gas emission generated from a planarization layer during the process of manufacturing the display device, and effectively preventing moisture penetration into the display area of the display device.

The display device according to the examples, aspects, and embodiments herein can be described as follows.

According to the one or more example embodiments described herein, a display device can be provided that includes a substrate, a display area for displaying an image and a non-display area outside of the display area, a planarization layer disposed over the substrate, located in the display area, and extending to a portion of the non-display area, a first mid-stopper located in the non-display area and disposed outside of the planarization layer, a second mid-stopper disposed outside of the first mid-stopper, a first metal pattern located in the non-display area and disposed on the first mid-stopper and the second mid-stopper, a second metal pattern located in the non-display area and disposed on the first metal pattern, and a first trench located between the first mid-stopper and the second mid-stopper. In one or more aspects, the first metal pattern and the second metal pattern may be disconnected at the first trench.

In one or more aspects, the display device may further include at least one light emitting element disposed in the display area and including a pixel electrode, an emission layer, and a common electrode. In one or more aspects, the second metal pattern may be electrically connected to the common electrode.

In one or more aspects, the display device may further include a light emitting element disposed in the display area and including a pixel electrode, an emission layer, and a common electrode, and a transistor connected to the pixel electrode. In one or more aspects, the first metal pattern may include a same material as a connecting electrode connecting a source electrode or drain electrode of the transistor and the pixel electrode, and the second metal pattern may include a same material as the pixel electrode.

In one or more aspects, the first metal pattern may be disposed on an inner side surface, an upper surface, and an outer side surface of the first mid-stopper, and be disposed on an inner side surface, an upper surface, and an outer side surface of the second mid-stopper.

In one or more aspects, the second metal pattern may be disposed on the first metal pattern at an inward location from the first trench, extend to an outer side surface of the first metal pattern at an inward location from the first trench, be disposed on the first metal pattern at an outward location from the first trench, and extend to an inner side surface of the first metal pattern at an outward location from the first trench.

In one or more aspects, a thickness of the first metal pattern may be greater than a thickness of the second metal pattern.

In one or more aspects, the planarization layer may include a first planarization layer disposed on the substrate and a second planarization layer disposed on the first planarization layer. In one or more aspects, the first metal pattern may be disposed in a metal layer between the first planarization layer and the second planarization layer and extend to an outward area from the first planarization layer, and the second metal pattern may be disposed on the second planarization layer and extend to an outward area from the second planarization layer. In one or more aspects, the first mid-stopper and the second mid-stopper may include a same material as the first planarization layer.

In one or more aspects, the display device may further include a common voltage line disposed in a metal layer between the substrate and the first planarization layer, electrically connected to the first metal pattern, and disposed under the first mid-stopper and the second mid-stopper. The common voltage line may also be referred to as a first common voltage line, a low common voltage line, or a low driving voltage line.

In one or more aspects, the display device may further include an organic layer located on an inner surface of the first trench and disposed between the first metal pattern and the second metal pattern. In one or more aspects, the organic layer may include a same material as the second planarization layer.

In one or more aspects, the display device may further include a light emitting element disposed on the planarization layer, a first inorganic encapsulating layer disposed on the light emitting element, an organic encapsulating layer disposed on the first inorganic encapsulating layer, and a second inorganic encapsulating layer disposed on the organic encapsulating layer. In one or more aspects, at least one of the first inorganic encapsulating layer and the second inorganic encapsulating layer may extend further outwardly than the organic encapsulating layer, and at least one of the first inorganic encapsulating layer and the second inorganic encapsulating layer may extend across the first trench without being disconnected at the first trench.

In one or more aspects, the display device may further include a third mid-stopper disposed on the planarization layer, overlapping with an edge of the organic encapsulating layer, and disposed to extend further outwardly than an area where the organic encapsulating layer is disposed.

In one or more aspects, the display device may further include a dam located further outwardly than the second mid-stopper. In one or more aspects, at least one of the first inorganic encapsulating layer and the second inorganic encapsulating layer may be disposed on the dam and extend to an outward area from the dam.

In one or more aspects, at least one of the first metal pattern and the second metal pattern may extend under at least a portion of the dam.

In one or more aspects, the display device may further include a bank disposed on the planarization layer, and a spacer disposed on the bank. In one or more aspects, the planarization layer may include a first planarization layer disposed on the substrate and a second planarization layer disposed on the first planarization layer. In one or more aspects, the first mid-stopper and the second mid-stopper may include a same material as the first planarization layer, and the dam may include a same material as the second planarization layer, a same material as the bank, and a same material as the spacer.

In one or more aspects, the display device may further include a second trench disposed between the dam and the second mid-stopper in the non-display area. In one or more aspects, the first metal pattern and the second metal pattern may be disconnected at the second trench, and at least one of the first inorganic encapsulating layer and the second inorganic encapsulating layer may extend across the first trench without being disconnected at the second trench.

In one or more aspects, heights from a lower surface of the substrate to respective uppermost portions of the first mid-stopper and the second mid-stopper may be less than a height from the lower surface of the substrate to an uppermost portion of the dam.

According to the one or more example embodiments described herein, a display device can be provided that includes substrate, a display area for displaying an image and a non-display area outside of the display area, a planarization layer disposed over the substrate and extending from the display area to a portion of the non-display area, a common electrode disposed on the planarization layer and extending from the display area to a portion of the non-display area, a first mid-stopper disposed outside of the planarization layer and surrounding the display area, a second mid-stopper surrounding the first mid-stopper and spaced apart from the first mid-stopper, a trench located between the first mid-stopper and the second mid-stopper, and a metal pattern located in the non-display area, disposed on the first mid-stopper and the second mid-stopper, and disconnected at the trench. In one or more aspects, a portion of the metal pattern disposed on the first mid-stopper may be electrically connected to the common electrode.

In one or more aspects, the display device may further include a dam surrounding the second mid-stopper and spaced apart from the second mid-stopper, and a common voltage line allowing a common voltage to be applied, electrically connected to the metal pattern, and disposed under the first mid-stopper and the second mid-stopper. In one or more aspects, the common voltage line may be disposed under the dam and overlaps with at least a portion of the dam.

According to the examples, aspects, and embodiments described herein, a display device may be provided that has a structure capable of preventing a phenomenon in which a portion of an encapsulation layer overflows during a process of manufacturing the display device.

According to the examples, aspects, and embodiments described herein, a display device may be provided that has a structure capable of preventing undesired substances such as moisture, oxygen, and the like from penetrating into a display area due to damage to a stackup structure of a display panel.

According to the examples, aspects, and embodiments described herein, a display device may be provided that is capable of blocking a penetration path of undesired substances such as moisture, oxygen, and the like through metal from a non-display area to a display area.

According to the examples, aspects, and embodiments described herein, a display device may be provided that is capable of minimizing damage to a stackup structure due to gas generated or emitted from various structures or configurations including organic materials during the process of manufacturing the display device.

According to the examples, aspects, and embodiments described herein, a display device may be provided that has a structure capable of preventing damage to a light emitting element that may occur by the process of manufacturing the display device.

According to the examples, aspects, and embodiments described herein, a display device may be provided that has a structure capable of preventing damage to a light emitting element in a display area and resulting display artifacts such as dark spots due to the penetration of undesired substances such as moisture, oxygen, and the like in a non-display area.

According to the examples, aspects, and embodiments described herein, a display device may be provided that is capable of preventing the penetration of undesired substances such as moisture, oxygen, and the like from the outside, to the inside, of a display panel during the process of manufacturing the display device, and thereby, preventing elements (e.g., light emitting elements, signal lines, electrodes, and the like) disposed inside of the display panel from being damaged or an electrical short circuit from occurring by the undesired substances.

According to the examples, aspects, and embodiments described herein, a display device may be provided that has a structure capable of preventing the penetration of undesired substances such as moisture, oxygen, and the like by utilizing one or more structures or configurations used in a display panel without adding a separate layer or pattern.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device, comprising:
a substrate;
a display area for displaying an image and a non-display area outside of the display area;
a planarization layer disposed over the substrate, located in the display area, and extending to a portion of the non-display area;
a first mid-stopper located in the non-display area and disposed outside of the planarization layer;
a second mid-stopper disposed outside of the first mid-stopper;
a first metal pattern located in the non-display area and disposed on the first mid-stopper and the second mid-stopper;
a second metal pattern located in the non-display area and disposed on the first metal pattern; and
a first trench located between the first mid-stopper and the second mid-stopper,
wherein each of the first metal pattern and the second metal pattern is disconnected at the first trench.

2. The display device of claim 1, further comprising: a common voltage line allowing a common voltage to be applied, electrically connected to the first metal pattern, and disposed under the first mid-stopper and the second mid-stopper.

3. The display device of claim 2, wherein the common voltage line is disconnected at the first trench.

4. The display device of claim 1, further comprising: a light emitting element disposed in the display area, and comprising a pixel electrode, an emission layer, and a common electrode,
wherein the second metal pattern is electrically connected to the common electrode.

5. The display device of claim 1, further comprising:
a light emitting element disposed in the display area, and comprising a pixel electrode, an emission layer, and a common electrode; and
a transistor connected to the pixel electrode,
wherein the first metal pattern comprises a same material as a connecting electrode connecting a source electrode or drain electrode of the transistor and the pixel electrode, and
wherein the second metal pattern comprises a same material as the pixel electrode.

6. The display device of claim 1, wherein the first metal pattern is disposed on an inner side surface, an upper surface, and an outer side surface of the first mid-stopper, and is disposed on an inner side surface, an upper surface, and an outer side surface of the second mid-stopper.

7. The display device of claim 1, wherein the second metal pattern is disposed on the first metal pattern at an inward location from the first trench, extends to an outer side surface of the first metal pattern at an inward location from the first trench, is disposed on the first metal pattern at an outward location from the first trench, and extends to an inner side surface of the first metal pattern at an outward location from the first trench.

8. The display device of claim 7, wherein a thickness of the first metal pattern is greater than a thickness of the second metal pattern.

9. The display device of claim 1, wherein the planarization layer comprises a first planarization layer disposed on the substrate and a second planarization layer disposed on the first planarization layer,
wherein the first metal pattern is disposed in a metal layer between the first planarization layer and the second planarization layer and extends to an outward area from the first planarization layer, and the second metal pattern is disposed on the second planarization layer and extends to an outward area from the second planarization layer, and
wherein the first mid-stopper and the second mid-stopper comprise a same material as the first planarization layer.

10. The display device of claim 9, further comprising: a common voltage line disposed in a metal layer between the substrate and the first planarization layer, electrically connected to the first metal pattern, and disposed under the first mid-stopper and the second mid-stopper.

11. The display device of claim 9, further comprising: an organic layer located on an inner surface of the first trench and disposed between the first metal pattern and the second metal pattern,
wherein the organic layer comprises a same material as the second planarization layer.

12. The display device of claim 1, further comprising:
a light emitting element disposed on the planarization layer;
a first inorganic encapsulating layer disposed on the light emitting element;
an organic encapsulating layer disposed on the first inorganic encapsulating layer; and
a second inorganic encapsulating layer disposed on the organic encapsulating layer,
wherein at least one of the first inorganic encapsulating layer and the second inorganic encapsulating layer extends further outwardly than the organic encapsulating layer, and
wherein at least one of the first inorganic encapsulating layer and the second inorganic encapsulating layer extends across the first trench without being disconnected at the first trench.

13. The display device of claim 12, further comprising: a third mid-stopper disposed on the planarization layer, overlapping with an edge of the organic encapsulating layer, and disposed to extend further outwardly than an area where the organic encapsulating layer is disposed.

14. The display device of claim 12, further comprising: a dam located further outwardly than the second mid-stopper,
wherein at least one of the first inorganic encapsulating layer and the second inorganic encapsulating layer is disposed on the dam and extends to an outward area from the dam.

15. The display device of claim 14, wherein at least one of the first metal pattern and the second metal pattern extends under at least a portion of the dam.

16. The display device of claim 14, further comprising:
a bank disposed on the planarization layer; and
a spacer disposed on the bank,
wherein the planarization layer comprises a first planarization layer disposed on the substrate and a second planarization layer disposed on the first planarization layer, and
wherein the first mid-stopper and the second mid-stopper comprise a same material as the first planarization layer, and the dam comprises a same material as the second planarization layer, a same material as the bank, and a same material as the spacer.

17. The display device of claim 14, further comprising: a second trench disposed between the dam and the second mid-stopper in the non-display area,
wherein the first metal pattern and the second metal pattern are disconnected at the second trench, and
wherein at least one of the first inorganic encapsulating layer and the second inorganic encapsulating layer extends across the first trench without being disconnected at the second trench.

18. The display device of claim 14, wherein heights from a lower surface of the substrate to respective uppermost portions of the first mid-stopper and the second mid-stopper are less than a height from the lower surface of the substrate to an uppermost portion of the dam.

19. A display device, comprising:
a substrate;
a display area for displaying an image and a non-display area outside of the display area;
a planarization layer disposed over the substrate and extending from the display area to a portion of the non-display area;
a common electrode disposed on the planarization layer and extending from the display area to a portion of the non-display area;
a first mid-stopper disposed outside of the planarization layer and surrounding the display area;
a second mid-stopper surrounding the first mid-stopper and spaced apart from the first mid-stopper;
a trench located between the first mid-stopper and the second mid-stopper; and
a metal pattern located in the non-display area, disposed on the first mid-stopper and the second mid-stopper, and disconnected at the trench,
wherein a portion of the metal pattern disposed on the first mid-stopper is electrically connected to the common electrode.

20. The display device of claim 19, further comprising:
a dam surrounding the second mid-stopper and spaced apart from the second mid-stopper; and
a common voltage line allowing a common voltage to be applied, electrically connected to the metal pattern, and disposed under the first mid-stopper and the second mid-stopper,
wherein the common voltage line is disposed under the dam and overlaps with at least a portion of the dam.
